(19) United States
(12) Patent Application Publication
(10) Pub. No.: US 2026/0107610 A1
(43) Pub. Date: Apr. 16, 2026

(54) DISPLAY PANEL AND ELECTRONIC DEVICE INCLUDING THE SAME

(71) Applicant: Samsung Display Co., Ltd., Yongin-si (KR)

(72) Inventors: Junsu Park, Yongin-si (KR); Junhyeong Park, Yongin-si (KR)

(21) Appl. No.: 19/349,643

(22) Filed: Oct. 3, 2025

(30) Foreign Application Priority Data
Oct. 11, 2024 (KR) 10-2024-0138624

(51) Int. Cl. H10H 29/41; H10H 29/32; H10H 29/49; H10H 29/85

(52) U.S. Cl. CPC H10H 29/41; H10H 29/32; H10H 29/49; H10H 29/8508

(57) ABSTRACT

A display panel includes a base layer, first and second pixel circuit layers on the base layer, each of the first and second pixel circuit layers including a transistor and insulating layers, a first light-emitting diode on the first pixel circuit layer, a second light-emitting diode on the second pixel circuit layer, and a protective layer on the first and second light-emitting diodes. The insulating layers of each of the first and second pixel circuit layers include an inorganic insulating stack and a first organic insulating layer on the inorganic insulating stack, the first organic insulating layer of the first pixel circuit layer includes first grooves arranged along an edge thereof and is space from the second pixel circuit layer, and a portion of the protective layer is in each of the first grooves.

### CROSS-REFERENCE TO RELATED APPLICATION

This application claims priority to and the benefit of Korean Patent Application No. 10-2024-0138624, filed on Oct. 11, 2024, in the Korean Intellectual Property Office, the entire disclosure of which is incorporated by reference herein.

### BACKGROUND

### 1. Field

One or more embodiments relate to a display panel. One or more embodiments relate to a display panel, a process of manufacturing the display panel, and an electronic device including the display panel.

### 2. Description of the Related Art

With the development of display panels that visually display electrical signals, various display panels having excellent characteristics, such as thinness, light weight, and low power consumption, and electronic devices including the same have been introduced. For example, research and development has been actively conducted into display panels having various structures, such as flexible display panels, rollable display panels, and/or stretchable display panels, and electronic devices including the same.

### SUMMARY

One or more embodiments include a display panel, for example, a flexible display panel, an electronic device including the display panel, and a process of manufacturing the display panel.

Additional aspects will be set forth in part in the description which follows and, in part, will be apparent from the description, or may be learned by practice of the presented embodiments of the present disclosure.

According to one or more embodiments, a display panel includes a base layer, a first pixel circuit layer on the base layer, the first pixel circuit layer including a transistor and insulating layers, a second pixel circuit layer on the base layer and spaced from the first pixel circuit layer, the second pixel circuit layer including a transistor and insulating layers, a first light-emitting diode on the first pixel circuit layer and electrically connected to the transistor of the first pixel circuit layer, a second light-emitting diode on the second pixel circuit layer and electrically connected to the transistor of the second pixel circuit layer, and a protective layer on the first light-emitting diode and the second light-emitting diode, wherein the insulating layers of each of the first pixel circuit layer and the second pixel circuit layer include an inorganic insulating stack including inorganic insulating layers and a first organic insulating layer on the inorganic insulating stack, the first organic insulating layer of the first pixel circuit layer and the first organic insulating layer of the second pixel circuit layer are spaced from each other, and the first organic insulating layer of the first pixel circuit layer includes first grooves arranged along an edge thereof and a portion of the protective layer is in each of the first grooves.

Each of the first grooves may include a first portion having a first width and a second portion spatially connected to the first portion and having a second width greater than the first width.

The first portion of each of the first grooves may extend toward the edge of the first organic insulating layer and, in a plan view, the first portion of each of the first grooves may be between the edge of the first organic insulating layer and the second portion of each of the first grooves.

The display panel may further include a first line electrically connected to the transistor of the first pixel circuit layer, a second line electrically connected to the transistor of the second pixel circuit layer, and a connection line electrically connecting the first line to the second line.

The first line may be between two adjacent first grooves from among the first grooves.

The first organic insulating layer of the first pixel circuit layer may overlap a connection point of the first line and the connection line.

The insulating layers of the first pixel circuit layer may further include a second organic insulating layer on the first organic insulating layer, the second organic insulating layer may include a second groove at an edge of the second organic insulating layer, and a portion of the protective layer may be in the second groove.

The second groove may include a first portion and a second portion spatially connected to the first portion and having a width greater than a width of the first portion.

The insulating layers of the first pixel circuit layer may further include a third organic insulating layer covering a side surface of the inorganic insulating stack of the first pixel circuit layer and, in a plan view, the third organic insulating layer may have a frame shape.

The protective layer and the base layer may include a same material.

According to one or more embodiments, a display panel includes a base layer including a first surface and a second surface opposite to the first surface, a first pixel circuit layer on the first surface of the base layer, the first pixel circuit layer including a transistor and insulating layers, a second pixel circuit layer on the first surface of the base layer and spaced from the first pixel circuit layer, the second pixel circuit layer including a transistor and insulating layers, a first light-emitting diode on the first pixel circuit layer and electrically connected to the transistor of the first pixel circuit layer, a second light-emitting diode on the second pixel circuit layer and electrically connected to the transistor of the second pixel circuit layer, a protective layer on the first light-emitting diode and the second light-emitting diode, a first line electrically connected to the transistor of the first pixel circuit layer, a second line electrically connected to the transistor of the second pixel circuit layer, and a connection line electrically connecting the first line to the second line, the insulating layers of each of the first pixel circuit layer and the second pixel circuit layer include a first organic insulating layer, the first organic insulating layer of the first pixel circuit layer and the first organic insulating layer of the second pixel circuit layer being spaced from each other, and the first organic insulating layer of the first pixel circuit layer includes a first groove at an edge of the first organic insulating layer, the first groove includes a first portion having a first width and a second portion having a second width different from the first width, and a portion of the protective layer is in the first groove.

The second width may be greater than the first width.

The first portion of the first groove may extend toward the edge of the first organic insulating layer.

The first organic insulating layer of the first pixel circuit layer may overlap a connection point of the first line and the connection line.

The insulating layers of the first pixel circuit layer may further include a second organic insulating layer on the first organic insulating layer, the second organic insulating layer may include a second groove at an edge of the second organic insulating layer, and a portion of the protective layer may be in the second groove.

The second groove may overlap the first organic insulating layer.

The second groove may include a first portion and a second portion spatially connected to the first portion and having a width greater than a width of the first portion.

The insulating layers of the first pixel circuit layer may further include an inorganic insulating stack between the base layer and the first organic insulating layer, and the first groove may not overlap the inorganic insulating stack.

The protective layer may be in direct contact with the connection line and the base layer.

The protective layer and the base layer may include a same material.

In one or more embodiments, an electronic device including a display panel, the display panel includes: a base layer; a first pixel circuit layer on the base layer, the first pixel circuit layer including a transistor and insulating layers; a second pixel circuit layer on the base layer and spaced from the first pixel circuit layer, the second pixel circuit layer including a transistor and insulating layers; a first light-emitting diode on the first pixel circuit layer and electrically connected to the transistor of the first pixel circuit layer; a second light-emitting diode on the second pixel circuit layer and electrically connected to the transistor of the second pixel circuit layer; and a protective layer on the first light-emitting diode and the second light-emitting diode, wherein the insulating layers of each of the first pixel circuit layer and the second pixel circuit layer include: an inorganic insulating stack including inorganic insulating layers; and a first organic insulating layer on the inorganic insulating stack, wherein the first organic insulating layer of the first pixel circuit layer and the first organic insulating layer of the second pixel circuit layer are spaced from each other, and wherein the first organic insulating layer of the first pixel circuit layer includes first grooves arranged along an edge thereof and a portion of the protective layer is in each of the first grooves.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a perspective view schematically illustrating a display panel according to one or more embodiments;

FIGS. 2A and 2B are perspective views illustrating the display panel of FIG. 1, which is stretched in a first direction;

FIG. 2C is a perspective view illustrating the display panel of FIG. 1, which is stretched in a second direction;

FIG. 2D is a perspective view illustrating the display panel of FIG. 1, which is stretched in the first direction and the second direction;

FIG. 2E is a perspective view illustrating the display panel of FIG. 1, which is stretched in a third direction;

FIG. 3 is a plan view schematically illustrating a display area of a display panel according to one or more embodiments;

FIG. 4 is a cross-sectional view of a first region of FIG. 3;

FIG. 5A-5C are equivalent circuit diagrams of a pixel of a display panel, according to one or more embodiments;

FIG. 6A-6E are cross-sectional views schematically illustrating a light-emitting diode of a display panel, according to one or more embodiments;

FIG. 7 is a plan view schematically illustrating a portion of a display area of a display panel, according to one or more embodiments;

FIG. 8 is a plan view schematically illustrating a portion of a display area of a display panel, according to one or more embodiments;

FIG. 9 is a cross-sectional view of the display panel of FIG. 7 taken along the line IX-IX′ of FIG. 7;

FIG. 10A is a plan view illustrating a first organic insulating layer, a third organic insulating layer, an inorganic insulating stack, a line, and a connection line, which are disposed in a first region of a display panel, according to one or more embodiments;

FIG. 10B is a plan view illustrating a first organic insulating layer and a second organic insulating layer, which are disposed in a first region of a display panel, according to one or more embodiments;

FIG. 11 is a cross-sectional view of the display panel of FIG. 10A taken along the line XI-XI′ of FIG. 10A;

FIG. 12 is a cross-sectional view of the display panel of FIG. 10A taken along the line XII-XII′ of FIG. 10A;

FIG. 13 is a cross-sectional view of the display panel of FIG. 10A taken along the line XIII-XIII′ of FIG. 10A;

FIG. 14 is a cross-sectional view illustrating a portion of a display panel according to one or more embodiments;

FIG. 15 is a plan view illustrating a first organic insulating layer, an inorganic insulating stack, a line, and a connection line, which are disposed in a first region of a display panel, according to one or more embodiments;

FIG. 16 is a cross-sectional view of the display panel of FIG. 15 taken along the line XVI-XVI′ of FIG. 15;

FIG. 17A-17H are cross-sectional views schematically illustrating a process of manufacturing a display panel, according to one or more embodiments;

FIG. 18 is a perspective view schematically illustrating an electronic device including a display panel, according to one or more embodiments;

FIG. 19 is a block diagram illustrating an electronic device including a display panel, according to one or more embodiments; and

FIGS. 20 and 21 are perspective views illustrating an electronic device according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items.

Throughout the present disclosure, the expression “at least one of a, b or c” or “at least one selected from a, b and c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the present disclosure, and methods of achieving them will be clarified with reference to embodiments described below in detail with reference to the drawings. However, the present disclosure is not limited to the following embodiments and may be embodied in various forms.

Hereinafter, embodiments will be described in detail with reference to the accompanying drawings. When describing the embodiments with reference to the accompanying drawings, the same or corresponding elements are denoted by the same reference numerals, and redundant descriptions thereof will be omitted.

In the following embodiments, the terms “first,” “second,” etc. are not used in a restrictive sense and are used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, it may be directly on the other layer, region, or element, but also intervening layers, regions, or elements may be present therebetween.

Also, sizes of elements in the drawings may be exaggerated or reduced for convenience of explanation. For example, because sizes and thicknesses of elements in the drawings are arbitrarily illustrated for convenience of explanation, the present disclosure is not necessarily limited thereto.

When a certain embodiment is implemented differently, a specific process sequence may be performed differently from a sequence described herein. For example, two consecutively described processes may be performed substantially at the same time or performed in an order opposite to the stated order.

It will be further understood that, when layers, regions, or elements are referred to as being connected to each other, they may be directly connected to each other or indirectly connected to each other with intervening layers, regions, or elements therebetween. For example, when layers, regions, or elements are referred to as being electrically connected to each other, they may be directly electrically connected to each other or indirectly electrically connected to each other with intervening layers, regions, or elements therebetween.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

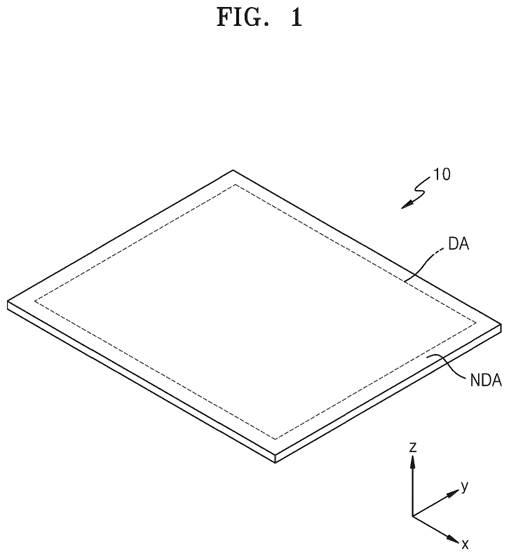

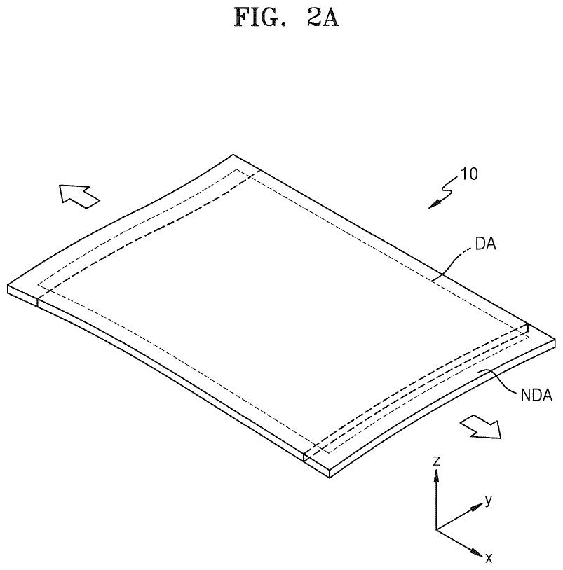

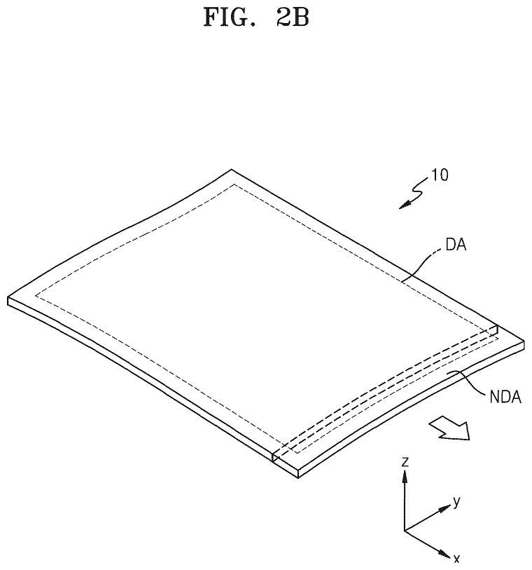

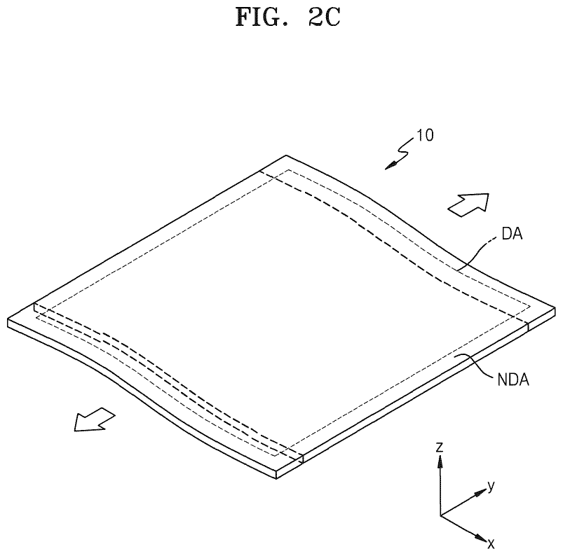

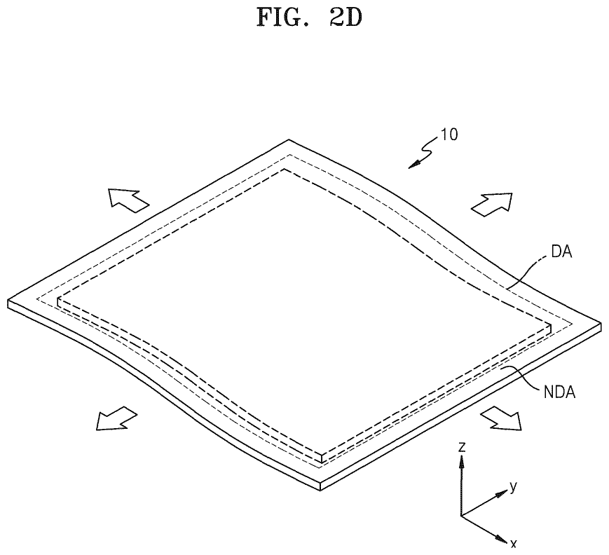

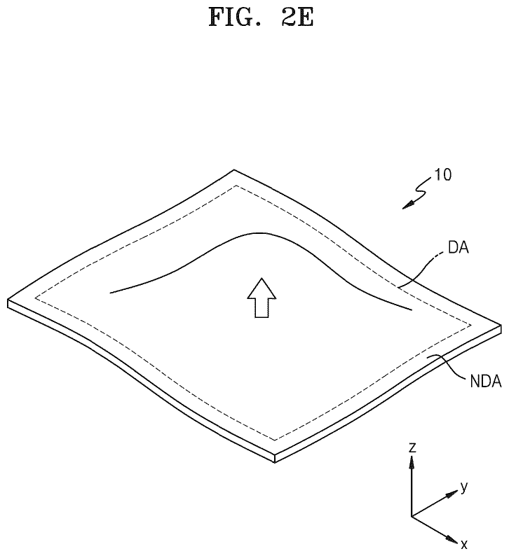

FIG. 1 is a perspective view schematically illustrating a display panel 10 according to one or more embodiments. FIGS. 2A and 2B are perspective views illustrating the display panel 10 of FIG. 1, which is stretched in a first direction. FIG. 2C is a perspective view illustrating the display panel 10 of FIG. 1, which is stretched in a second direction. FIG. 2D is a perspective view illustrating the display panel 10 of FIG. 1, which is stretched in the first direction and the second direction. FIG. 2E is a perspective view illustrating the display panel 10 of FIG. 1, which is stretched in a third direction.

Referring to FIG. 1, the display panel 10 may include a display area DA and a non-display area NDA disposed around the display area DA along an edge or a periphery of the display area DA. The display area DA may include a plurality of pixels. The display panel 10 may provide a certain image by using light emitted from the plurality of pixels. The non-display area NDA may be disposed outside the display area DA. The non-display area NDA may completely surround the display area DA.

The display panel 10 may be stretched or contracted in various directions. The display panel 10 may be stretched in the first direction (e.g., the +x direction and/or the −x direction) by an external force applied by an external object or a user. In one or more embodiments, as illustrated in FIGS. 2A and 2B, the display area DA and/or the non-display area NDA of the display panel 10 may be stretched in the first direction (e.g., the +x direction and/or the −x direction). For example, as illustrated in FIG. 2A, the display panel 10 may be stretched in the +x direction and the −x direction, or as illustrated in FIG. 2B, the display panel 10 may be stretched in the +x direction while one side of the display panel 10 is fixed.

The display panel 10 may be stretched in the second direction (e.g., the +y direction and/or the −y direction) by an external force applied by an external object or a user. In one or more embodiments, as illustrated in FIG. 2C, the display area DA and/or the non-display area NDA of the display panel 10 may be stretched in the +y direction and the −y direction. In another embodiment, the display panel 10 may be stretched in the +y direction or the −y direction while one side of the display panel 10 is fixed.

The display panel 10 may be stretched in a plurality of directions, for example, the first direction (e.g., the +x direction and/or the −x direction) and the second direction (e.g., the +y direction and/or the −y direction) by an external force applied by an external object or a part of a user's body. As illustrated in FIG. 2D, the display area DA and/or the non-display area NDA of the display panel 10 may be stretched in the ±x direction and the ±y direction.

The display panel 10 may be stretched in the third direction (e.g., the +z direction or the −z direction) by an external force applied by an external object or a part of a user's body. In one or more embodiments, FIG. 2E illustrates that a portion of the display panel 10, for example, a portion of the display area DA, protrudes in the +z direction. In another embodiment, a portion of the display panel 10, for example, a portion of the display area DA, may protrude in the +z direction (or may be recessed in the −z direction).

FIG. 2A-2E illustrate that the display panel 10 is stretched in the first direction (e.g., ±x direction), the second direction (e.g., ±y direction), and/or the third direction (e.g., ±z direction), but the present disclosure is not limited thereto. In another embodiment, the display panel 10 may be deformed into various irregular shapes. For example, the display panel 10 may be bent and/or twisted with respect to two or more axes.

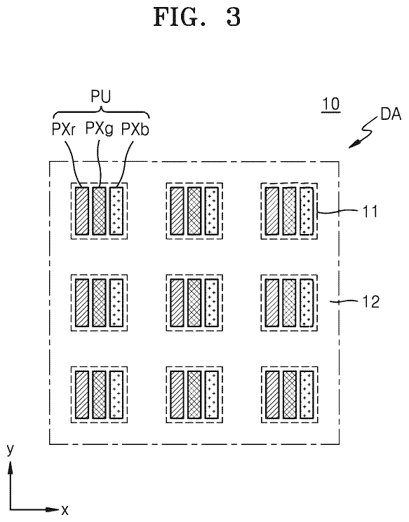

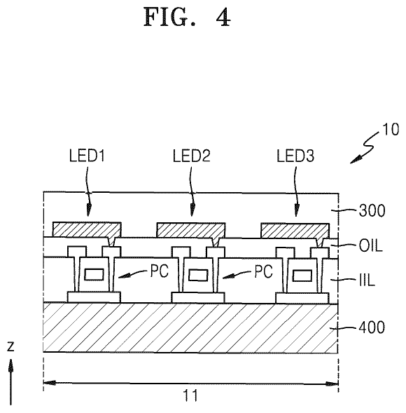

FIG. 3 is a plan view schematically illustrating a display area DA of a display panel 10 according to one or more embodiments, and FIG. 4 is a cross-sectional view of a first region of FIG. 3.

Referring to FIG. 3, the display area DA may include first regions 11 and a second region 12 around (e.g., surrounding) each of the first regions 11. The first regions 11 may be repeatedly disposed along the first direction (e.g., the x direction) and the second direction (e.g., the y direction).

The display area DA may include the first region 11 and the second region 12 having different elongations. For example, the display panel 10 may include the first region 11 having a relatively small elongation and the second region 12 having a relatively large elongation. In the present disclosure, the elongation is a numerical value representing a change in length (ΔL/L) by which the display panel 10 may be stretched without physical damage to the display panel 10 when an external force is applied to the display panel 10. ΔL represents a change in length of the display panel 10 and L represents the initial length of the display panel 10. Therefore, the elongation of the first region 11 and the elongation of the second region 12 may respectively represent the change in length of the first region 11 and the change in length of the second region 12 when the same external force is applied to the first region 11 and the second region 12.

The expression that the elongation of the first region 11 is less than the elongation of the second region 12 may mean that the first region 11 is relatively less deformed due to an external force. Therefore, the first region 11 may be referred to as a low deformation region and the second region 12 may be referred to as a high deformation region.

The first regions 11 may be two-dimensionally spaced (e.g., spaced apart) from each other in the display area DA. The first region 11 may be a region where pixels are disposed. Accordingly, the first region 11 may be referred to as a pixel area or an emission area. One or more pixels may be disposed in each of the first regions 11. Pixel units PU each including a set of pixels may be provided in the first region 11. Each of the pixel units PU may include a red pixel PXr, a green pixel PXg, and a blue pixel PXb.

The red pixel PXr, the green pixel PXg, and the blue pixel PXb may respectively include a first light-emitting diode LED1, a second light-emitting diode LED2, and a third light-emitting diode LED3. Referring to FIG. 4, the first region 11 of the display panel 10 may include a pixel circuit PC, an inorganic insulating stack IIL, an organic insulating layer OIL, first to third light-emitting diodes LED1, LED2, and LED3 electrically connected to the pixel circuits PC, and a protective layer 300, which are disposed above a base layer 400. The elongation of the first region 11 may be relatively less than the elongation of the second region 12 due to the stacked structure of the pixel circuits PC, the inorganic insulating stack IIL, the organic insulating layer OIL, and the first to third light-emitting diodes LED1, LED2, and LED3, which are disposed in the first region 11.

The second region 12 may be disposed between the adjacent first regions 11. As illustrated in FIG. 3, in a plan view, the second region 12 may have a shape that surrounds the first region 11. The second region 12 may be a region through which connection lines electrically connected to the pixel circuits (see PC of FIG. 4) respectively disposed in two adjacent first regions 11 pass.

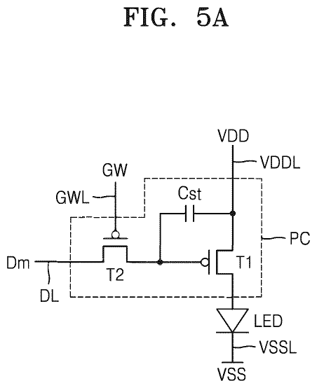

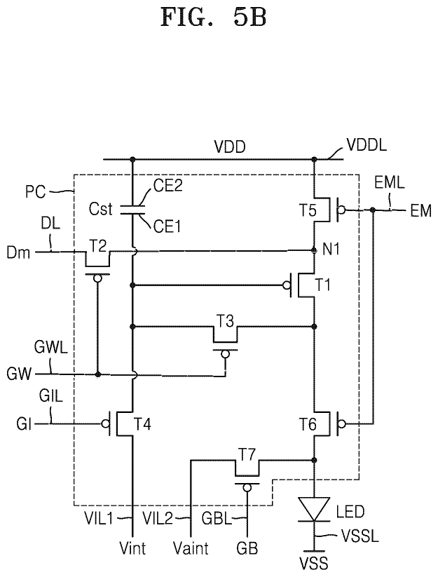

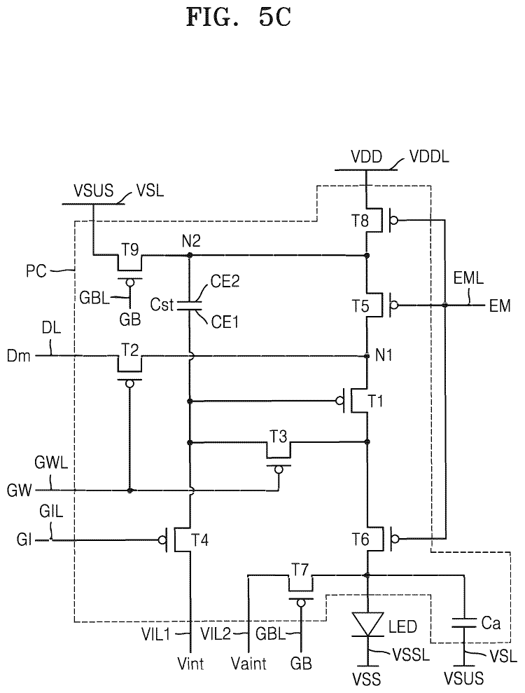

FIG. 5A-5C are equivalent circuit diagrams of a pixel of a display panel, according to one or more embodiments.

Referring to FIG. 5A, a light-emitting diode LED corresponding to a pixel may be electrically connected to a pixel circuit PC. The pixel circuit PC may include a first transistor T1, a second transistor T2, and a storage capacitor Cst. The pixel circuit PC may be electrically connected to signal lines and voltage lines. The signal lines may include a scan signal line GWL and a data line DL. The voltage lines may include a first voltage line VDDL and a second voltage line VSSL.

The second transistor T2 may be electrically connected to the scan signal line GWL and the data line DL. The scan signal line GWL may be configured to provide a scan signal GW to a gate electrode of the second transistor T2. The second transistor T2 may be configured to transmit, to the first transistor T1, a data signal Dm input from the data line DL, in response to the scan signal GW input from the scan signal line GWL.

The storage capacitor Cst may be electrically connected to the second transistor T2 and the first voltage line VDDL and may be configured to store a voltage corresponding to a difference between a voltage received from the second transistor T2 and a first power supply voltage VDD supplied through the first voltage line VDDL.

The first transistor T1, which acts as a driving transistor, may be configured to control a driving current flowing through the light-emitting diode LED. The first transistor T1 may be connected to the first voltage line VDDL and the storage capacitor Cst. The first transistor T1 may be configured to control the driving current flowing from the first voltage line VDDL to the light-emitting diode LED according to a voltage value stored in the storage capacitor Cst. The light-emitting diode LED may be configured to emit light having a certain luminance according to the driving current. A first electrode of the light-emitting diode LED may be electrically connected to the first transistor T1, and a second electrode of the light-emitting diode LED may be electrically connected to the second voltage line VSSL configured to supply a second power supply voltage VSS.

FIG. 5A illustrates that the pixel circuit PC includes two transistors and one storage capacitor, but in another embodiment, the pixel circuit PC may include three or more transistors.

Referring to FIG. 5B, a pixel circuit PC may include a first transistor T1, a second transistor T2, a third transistor T3, a fourth transistor T4, a fifth transistor T5, a sixth transistor T6, a seventh transistor T7, and a storage capacitor Cst.

The pixel circuit PC may be electrically connected to signal lines and voltage lines. The signal lines may include a data line DL and gate lines, such as, a scan signal line GWL, a bypass control line GBL, an initialization control line GIL, and an emission control line EML. The voltage lines may include first and second initialization voltage lines VIL1 and VIL2, a first voltage line VDDL, and a second voltage line VSSL.

The first voltage line VDDL may be configured to transmit a first power supply voltage VDD to the first transistor T1. The first initialization voltage line VIL1 may be configured to transmit, to the pixel circuit PC, a first initialization voltage Vint for initializing the first transistor T1. The second initialization voltage line VIL2 may be configured to transmit, to the pixel circuit PC, a second initialization voltage Vaint for initializing the first electrode of the light-emitting diode LED.

The first transistor T1 may be electrically connected to the first voltage line VDDL via the fifth transistor T5 and may be electrically connected to the light-emitting diode LED via the sixth transistor T6. The first transistor T1, which acts as a driving transistor, may be configured to receive a data signal Dm according to the switching operation of the second transistor T2 and supply a driving current to the light-emitting diode LED.

The second transistor T2, which acts as a data write transistor, may be electrically connected to the scan signal line GWL and the data line DL. The second transistor T2 may be electrically connected to the first voltage line VDDL via the fifth transistor T5. The second transistor T2 may be configured to be turned on in response to a scan signal GW received through the scan signal line GWL and perform a switching operation to transmit the data signal Dm received through the data line DL to a first node N1 connected to a first electrode of the first transistor T1.

The third transistor T3 may be electrically connected to the scan signal line GWL and electrically connected to the light-emitting diode LED via the sixth transistor T6. The third transistor T3 may be connected between a second electrode and a gate electrode of the first transistor T1. The third transistor T3 may be configured to be turned on in response to the scan signal GW received through the scan signal line GWL and diode-connect the first transistor T1.

The fourth transistor T4, which acts as a first initialization transistor, may be electrically connected to the initialization control line GIL and the first initialization voltage line VIL1. The fourth transistor T4 may be configured to be turned on in response to an initialization control signal GI received through the initialization control line GIL and initialize a voltage of the gate electrode of the first transistor T1 by transmitting the first initialization voltage Vint from the first initialization voltage line VIL1 to the gate electrode of the first transistor T1. The initialization control signal GI may correspond to a scan signal of another pixel circuit disposed in a previous row of the corresponding pixel circuit PC.

The fifth transistor T5 may act as an operation control transistor and the sixth transistor T6 may act as an emission control transistor. The fifth transistor T5 and the sixth transistor T6 may be electrically connected to the emission control line EML and may be configured to be concurrently (e.g., simultaneously) turned on in response to an emission control signal EM received through the emission control line EML and form a current path through which the driving current flows in a direction from the first voltage line VDDL to the light-emitting diode LED. The first electrode of the light-emitting diode LED may be electrically connected to the first transistor T1 through the sixth transistor T6, and the second electrode of the light-emitting diode LED may be electrically connected to a second voltage line VSSL configured to supply a second power supply voltage VSS.

The seventh transistor T7, which acts as a second initialization transistor, may be electrically connected to the bypass control line GBL, the second initialization voltage line VIL2, and the sixth transistor T6. The seventh transistor T7 may be configured to be turned on in response to a bypass control signal GB received through the bypass control line GBL and initialize the first electrode of the light-emitting diode LED by transmitting the second initialization voltage Vaint from the second initialization voltage line VIL2 to the first electrode of the light-emitting diode LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may store and maintain a voltage corresponding to a voltage difference between the first voltage line VDDL and the gate electrode of the first transistor T1, and thus, the voltage applied to the gate electrode of the first transistor T1 may be maintained.

Referring to FIG. 5C, a pixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel circuit PC may be electrically connected to signal lines and voltage lines. The signal lines may include a data line DL and gate lines, such as, a scan signal line GWL, a bypass control line GBL, an initialization control line GIL, and an emission control line EML. The voltage lines may include first and second initialization voltage lines VIL1 and VIL2, a sustain voltage line VSL, a first voltage line VDDL, and a second voltage line VSSL.

The first voltage line VDDL may be configured to transmit a first power supply voltage VDD to the first transistor T1. The first initialization voltage line VIL1 may be configured to transmit, to the pixel circuit PC, a first initialization voltage Vint for initializing the first transistor T1. The second initialization voltage line VIL2 may be configured to transmit, to the pixel circuit PC, a second initialization voltage Vaint for initializing a first electrode of a light-emitting diode LED. The sustain voltage line VSL may be configured to provide a sustain voltage VSUS to a second node N2, for example, a second electrode CE2 of the storage capacitor Cst, in an initialization period and a data write period.

The first transistor T1 may be electrically connected to the first voltage line VDDL via the fifth transistor T5 and the eighth transistor T8 and may be electrically connected to the light-emitting diode LED via the sixth transistor T6. The first transistor T1, which acts as a driving transistor, may be configured to receive a data signal Dm at a first electrode of the first transistor T1 according to the switching operation of the second transistor T2 and supply a driving current to the light-emitting diode LED.

The second transistor T2 may be electrically connected to the scan signal line GWL and the data line DL and electrically connected to the first voltage line VDDL via the fifth transistor T5 and the eighth transistor T8. The second transistor T2 may be configured to be turned on in response to a scan signal GW received through the scan signal line GWL and perform a switching operation to transmit the data signal Dm received through the data line DL to a first node N1 connected to the first electrode of the first transistor T1.

The third transistor T3 may be electrically connected to the scan signal line GWL and electrically connected to the light-emitting diode LED via the sixth transistor T6. The third transistor T3 may be connected between a second electrode and a gate electrode of the first transistor T1. The third transistor T3 may be configured to be turned on in response to the scan signal GW received through the scan signal line GWL and compensate for a threshold voltage of the first transistor T1 by diode-connecting the first transistor T1.

The fourth transistor T4 may be electrically connected to the initialization control line GIL and the first initialization voltage line VIL1 and may be configured to be turned on in response to an initialization control signal GI received through the initialization control line GIL and initialize a voltage of the gate electrode of the first transistor T1 by transmitting the first initialization voltage Vint from the first initialization voltage line VIL1 to the gate electrode of the first transistor T1. The initialization control signal GI may correspond to a scan signal of another pixel circuit disposed in a previous row of the corresponding pixel circuit PC.

The fifth transistor T5, the sixth transistor T6, and the eighth transistor T8 may be electrically connected to the emission control line EML and may be configured to be concurrently (e.g., simultaneously) turned on in response to an emission control signal EM received through the emission control line EML and form a current path through which the driving current flows in a direction from the first voltage line VDDL to the light-emitting diode LED. The first electrode of the light-emitting diode LED may be electrically connected to the first transistor T1 through the sixth transistor T6, and a second electrode of the light-emitting diode LED may be electrically connected to the second voltage line VSSL configured to supply a second power supply voltage VSS.

The seventh transistor T7, which acts as a second initialization transistor, may be electrically connected to the bypass control line GBL, the second initialization voltage line VIL2, and the sixth transistor T6. The seventh transistor T7 may be configured to be turned on in response to a bypass control signal GB received through the bypass control line GBL and initialize the first electrode of the light-emitting diode LED by transmitting the second initialization voltage Vaint from the second initialization voltage line VIL2 to the first electrode of the light-emitting diode LED.

The ninth transistor T9 may be electrically connected to the bypass control line GBL, the second electrode CE2 of the storage capacitor Cst, and the sustain voltage line VSL. The ninth transistor T9 may be configured to be turned on in response to the bypass control signal GB received through the bypass control line GBL and transmit the sustain voltage VSUS to the second node N2, for example, the second electrode CE2 of the storage capacitor Cst, in the initialization period and the data write period.

The eighth transistor T8 and the ninth transistor T9 may be electrically connected to the second node N2, for example, the second electrode CE2 of the storage capacitor Cst. In one or more embodiments, in the initialization period and the data write period, the eighth transistor T8 may be turned off and the ninth transistor T9 may be turned on, and in the emission period, the eighth transistor T8 may be turned on and the ninth transistor T9 may be turned off.

The storage capacitor Cst may include the first electrode CE1 and the second electrode CE2. The first electrode CE1 of the storage capacitor Cst may be electrically connected to the gate electrode of the first transistor T1, and the second electrode CE2 of the storage capacitor Cst may be electrically connected to the eighth transistor T8 and the ninth transistor T9.

The auxiliary capacitor Ca may be electrically connected to the sixth transistor T6, the sustain voltage line VSL, and the first electrode of the light-emitting diode LED. The auxiliary capacitor Ca may store and maintain a voltage corresponding to a voltage difference between the first electrode of the light-emitting diode LED and the sustain voltage line VSL while the seventh transistor T7 and the ninth transistor T9 are turned on, and thus, the problem that increases black luminance when the sixth transistor T6 is turned off may be prevented.

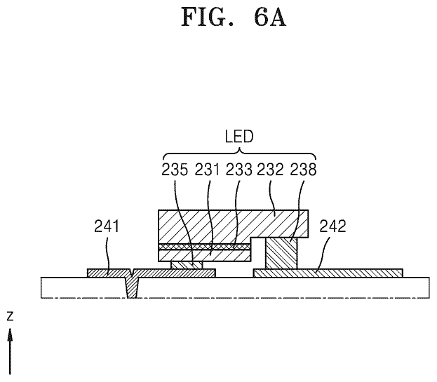

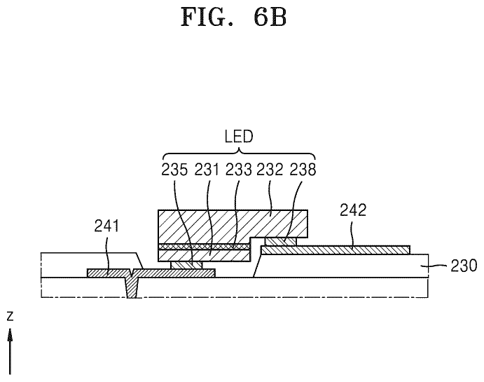

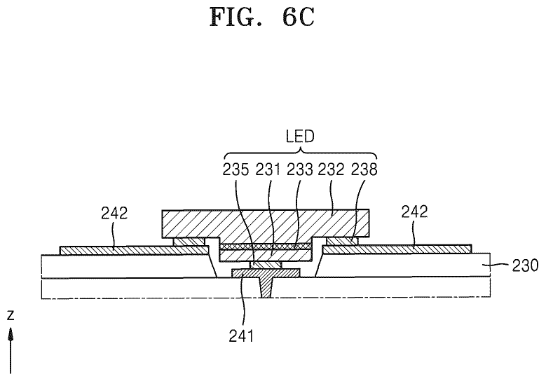

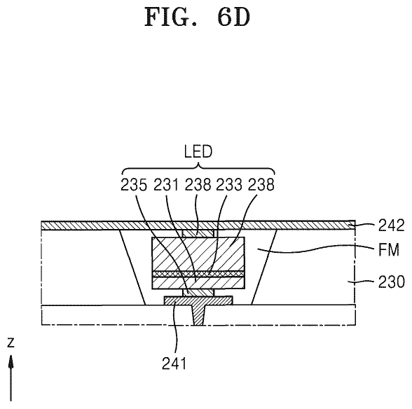

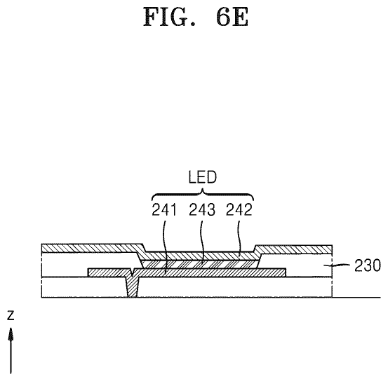

FIG. 6A-6E are cross-sectional views schematically illustrating a light-emitting diode of a display panel, according to one or more embodiments.

Referring to FIG. 6A, a light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be respectively electrically connected to a first electrode pad 241 and a second electrode pad 242, which are disposed on (or at) the same layer. The second electrode pad 242 may be a portion of the second voltage line (see VSSL of FIG. 5A) or may be a conductive layer electrically connected to the second voltage line (see VSSL of FIG. 5A).

In one or more embodiments, the first semiconductor layer 231 may include a p-type semiconductor layer. The p-type semiconductor layer may be selected from semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, and/or AlInN, and may be doped with a p-type dopant, such as Mg, Zn, Ca, Sr, and/or Ba.

The second semiconductor layer 232 may include, for example, an n-type semiconductor layer. The n-type semiconductor layer may be selected from semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, and/or AlInN, and may be doped with an n-type dopant, such as Si, Ge, and/or Sn.

The intermediate layer 233 is an area in which electrons and holes recombine. As the electrons and the holes recombine, the intermediate layer 233 may transition to a low energy level to generate light having a wavelength corresponding thereto. For example, the intermediate layer 233 may include a semiconductor material having a composition formula of InₓAl_{y}Ga_{1-x-y}N (0≤x≤1, 0≤y≤1, 0≤x+y≤1), and may have a single quantum well structure or a multi quantum well (MQW) structure. In addition, the intermediate layer 233 may have a quantum wire structure and/or a quantum dot structure.

Although FIG. 6A illustrates that the first semiconductor layer 231 includes a p-type semiconductor layer and the second semiconductor layer 232 includes an n-type semiconductor layer, the present disclosure is not limited thereto. In another embodiment, the first semiconductor layer 231 may include an n-type semiconductor layer and the second semiconductor layer 232 may include a p-type semiconductor layer.

Although FIG. 6A illustrates that the first electrode pad 241 and the second electrode pad 242 are disposed on (or at) the same layer, the present disclosure is not limited thereto. Referring to FIG. 6B, the first electrode pad 241 and the second electrode pad 242 may be disposed on different layers. For example, a bank layer 230 having an opening that overlaps at least a portion of the first electrode pad 241 may be disposed on the first electrode pad 241, and the second electrode pad 242 may be disposed on the upper surface of the bank layer 230. The structure of the light-emitting diode LED illustrated in FIG. 6B is the same as described above with reference to FIG. 6A.

In another embodiment, as illustrated in FIG. 6C, the second electrode pad 242 may be disposed on both sides of the first electrode pad 241 in a cross-sectional view. The bank layer 230 may include an opening that overlaps at least a portion of the first electrode pad 241, and the second electrode pad 242 may be disposed around the opening of the bank layer 230. In one or more embodiments, in a plan view, the second electrode pad 242 may have a closed loop shape that entirely surrounds the opening of the bank layer 230 and/or the first electrode pad 241. The structure of the light-emitting diode LED illustrated in FIG. 6C is the same as described above with reference to FIG. 6A.

Although FIG. 6A-6C illustrate that the first electrode 235 and the second electrode 238 of the light-emitting diode LED face the same direction (e.g., the downward direction or the −z direction), the present disclosure is not limited thereto. As illustrated in FIG. 6D, the first electrode 235 and the second electrode 238 of the light-emitting diode LED may face opposite directions.

The bank layer 230 may include an opening that exposes at least a portion of the first electrode pad 241. The thickness of the bank layer 230 may be substantially the same as the thickness of the light-emitting diode LED. The opening of the bank layer 230 may be filled with a filling material FM. The second electrode pad 242 may be disposed on the upper surface of the bank layer 230 so as to be electrically connected to (e.g., in contact with) the second electrode 238 of the light-emitting diode LED. The filling material FM may be an organic insulating material.

Although FIG. 6A-6D illustrate that the light-emitting diode LED includes an inorganic light-emitting diode including an inorganic material, the present disclosure is not limited thereto. Referring to FIG. 6E, the light-emitting diode LED may include an organic light-emitting diode including an organic material. For example, the light-emitting diode LED may include a first electrode pad (or a first electrode) 241, an organic light-emitting layer 243 overlapping the first electrode pad 241 through an opening of a bank layer 230 disposed on the first electrode pad 241, and second electrode pads (or second electrodes) 242 on the organic light-emitting layer 243. The second electrode pads 242 may be shared by light-emitting diodes LED. In other words, the second electrode pad 242 of one light-emitting diode LED may be integrally connected with the second electrode pad 242 of another light-emitting diode LED.

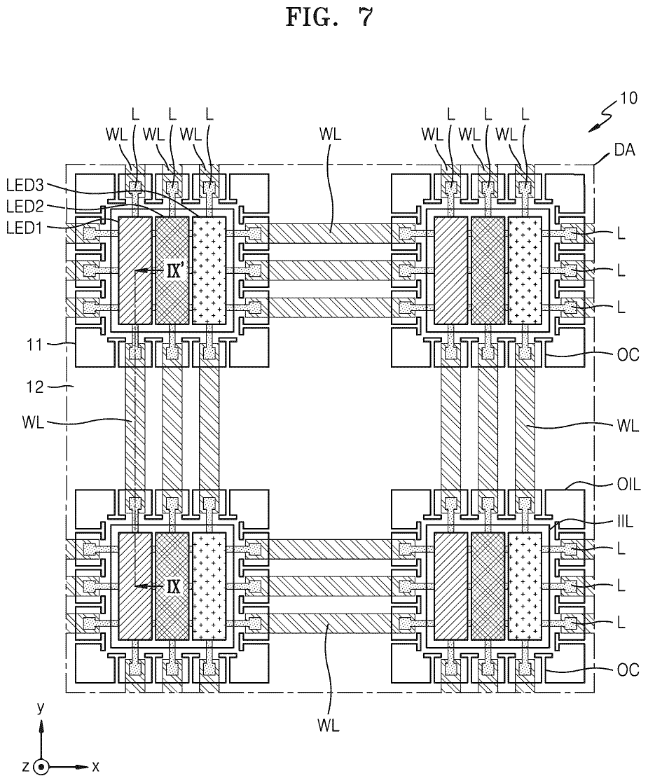

FIG. 7 is a plan view schematically illustrating a portion of a display area DA of a display panel 10, according to one or more embodiments. FIG. 7 illustrates light-emitting diodes, for example, first to third light-emitting diodes LED1, LED2, and LED3, which correspond to the pixels PXr, PXg, and PXb described with reference to FIG. 3. The light-emitting diodes may be electrically connected to pixel circuits. Each of the pixel circuits may be electrically connected to a conductive line L (hereinafter, referred to as a line).

Referring to FIG. 7 and FIG. 4, the pixel circuits (see PC of FIG. 4) configured to respectively drive the first to third light-emitting diodes LED1, LED2, and LED3 may be disposed in the first region 11.

The lines L electrically connected to the pixel circuits PC may be disposed in the display area DA. In one or more embodiments, FIG. 7 illustrates that the lines L extending in the first direction (e.g., the +x direction or the −x direction) and the lines L extending in the second direction (e.g., the +y direction or the −y direction) are electrically connected to the pixel circuits PC. The lines L may be electrically connected to the pixel circuits PC through contact holes, respectively.

One line L disposed in the first region 11 may be electrically connected to one line L disposed in the adjacent first region 11 through a connection line WL. The lines L may include voltage lines and/or signal lines. The lines L may include a gate line, a data line, and/or a voltage line. The gate line may be configured to provide a gate signal to a gate electrode of a transistor.

In one or more embodiments, the lines L extending in the first direction (e.g., the +x direction or the −x direction) in FIG. 7 may include the scan signal line GWL, the bypass control line GBL, the initialization control line GIL, the emission control line EML, and/or the second voltage line VSSL, which have been described above with reference to FIG. 5A-5C. The lines L extending in the second direction (e.g., the +y direction or the −y direction) may include the data line DL, the first initialization voltage line VIL1, the second initialization voltage line VIL2, the sustain voltage line VSL, and/or the first voltage line VDDL, which have been described above with reference to FIG. 5A-5C.

The connection lines WL disposed in the second region 12 may be stretched more than the lines L disposed in the first region 11. The elongation of each of the connection lines WL may be greater than the elongation of each of the lines L.

The lines L may each include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). In one or more embodiments, the lines L may each be a single layer or layers including the metal described above. In one or more embodiments, the lines L may each include a metal thin-film including a triple layer having a titanium (Ti)/aluminum (Al)/titanium (Ti) structure.

The connection lines WL may each include a liquid metal or a conductive composite material including a metal nanostructure, elastic polymer, and/or elastomer. Therefore, when the display panel (see 10 of FIG. 1) is stretched, high strain may occur in the connection line WL and the second region 12.

An inorganic insulating stack IIL and an organic insulating layer OIL may be disposed in the first region 11. The inorganic insulating stack IIL may include a plurality of inorganic insulating layers. The organic insulating layer OIL may be disposed on the inorganic insulating stack IIL. The first region 11 may be defined as a region when the inorganic insulating stack IIL and the organic insulating layer OIL are projected along (e.g., stacked along) a direction perpendicular to the base layer 400.

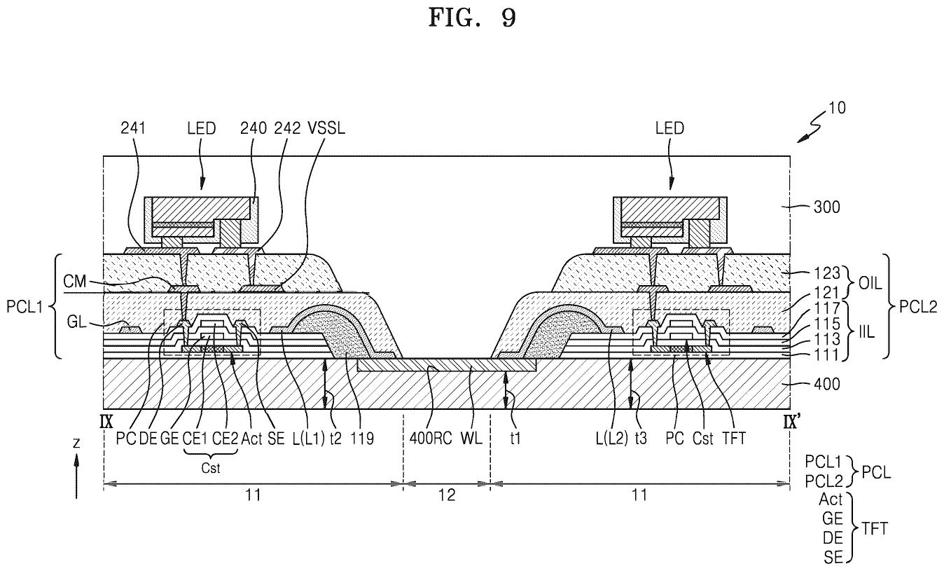

The inorganic insulating stack IIL and the organic insulating layer OIL may each have an isolated shape. In a plan view, the inorganic insulating stack IIL disposed in one first region 11 may be spaced (e.g., spaced apart) from the inorganic insulating stack IIL disposed in another first region 11. The organic insulating layer OIL disposed in one first region 11 may be spaced (e.g., spaced apart) from the organic insulating layer OIL disposed in another first region 11. The organic insulating layer OIL may include grooves OC. In a plan view, the grooves OC may be spaced (e.g., spaced apart) from each other along the periphery (e.g., a circumference) of each of the organic insulating layers OIL. As described below with reference to FIG. 9-14, the grooves OC may correspond to a type of bonding groove for improving bonding strength with a protective layer (see 300 of FIG. 9) disposed on the light-emitting diodes. A portion of the protective layer (see 300 of FIG. 9) may be disposed in the grooves OC, and thus, may prevent or minimize separation of the protective layer 300 when the display panel 10 is stretched.

The elongation of the first region 11 including the light-emitting diodes, the pixel circuit, the inorganic insulating stack IIL, and/or the organic insulating layer OIL may be less than the elongation of the second region 12. Accordingly, when the display panel 10 is stretched, the first region 11 may be less deformed than the second region 12. As described above, the first region 11 may be referred to as a low-strain region (or a low-strain portion). The first region 11 is a region where the light-emitting diodes are disposed and may be referred to as a pixel area or an emission area.

The second region 12 may surround each of the first regions 11 and may have a greater elongation than the first region 11. The second region 12 where the inorganic insulating stack IIL and the organic insulating layer OIL are not present may be relatively easily deformed. The second region 12 may be a region where main deformation occurs according to the stretching of the display device. The second region 12 is disposed between the plurality of first regions 11 and may be referred to as a connecting portion that connects the first regions 11 to each other. The second region 12 may be referred to as a main deformation region (or a main deformation portion) or a high deformation region (or a high deformation portion). The second region 12 is a region of the display area where no light-emitting diodes are disposed and may be referred to as a non-pixel area or a non-emission area.

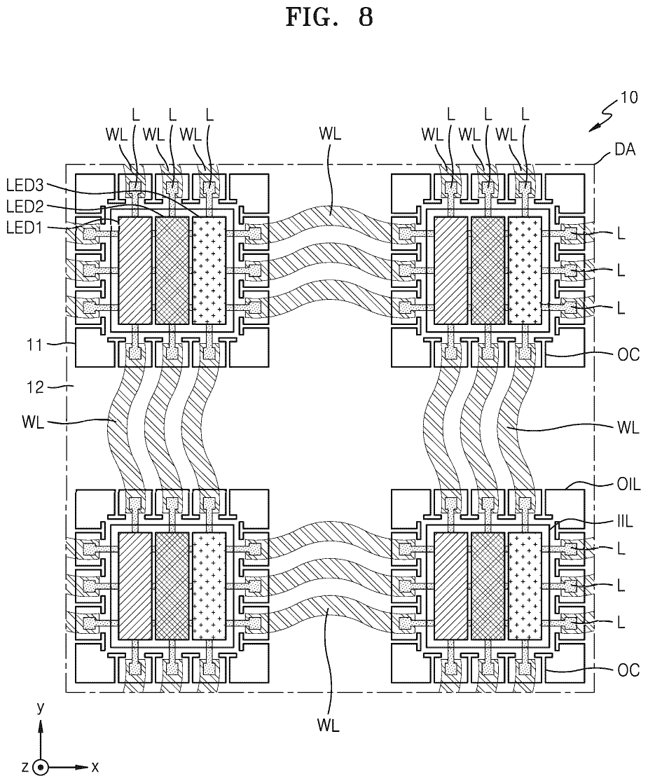

FIG. 8 is a plan view schematically illustrating a portion of a display area DA of a display panel 10, according to one or more embodiments.

In the embodiment described above with reference to FIG. 7, the connection line WL is illustrated as a straight line in a plan view, but the present disclosure is not limited thereto. As illustrated in FIG. 8, the connection line WL may have a shape other than a straight line in a plan view. The display panel 10 according to the embodiment of FIG. 8 is the same as the display panel 10 according to the embodiment of FIG. 7, except for the shape of the connection line WL in a plan view. Hereinafter, the same description is omitted and the differences are mainly described.

Referring to FIG. 8, the connection lines WL may each have a serpentine shape in a plan view. For example, in a plan view, the connection lines WL may each have a wave shape with two or more inflection points. When the connection line WL has a serpentine shape, deformation or damage of the connection line WL may be effectively prevented when the second region 12 is stretched. FIG. 8 illustrates that the connection line WL has a gentle C-shape in a plan view, but in another embodiment, the connection line WL may have a wave shape, such as an S-shape in a plan view.

FIG. 9 is a cross-sectional view of the display panel 10 of FIG. 7 taken along the line IX-IX′ of FIG. 7.

Referring to FIG. 9, the display panel 10 may include first regions 11 and a second region 12, and a portion of the second region 12 is between the first regions 11, as described above with reference to FIG. 7. Because components of the display panel 10 are disposed on a base layer 400, the expression that the display panel 10 includes the first region 11 and the second region 12 may correspond to the expression that the base layer 400 includes the first region 11 and the second region 12.

The display panel 10 may include pixel circuit layers PCL respectively disposed in two adjacent first regions 11 and light-emitting diodes LED respectively disposed on the pixel circuit layers PCL. The light-emitting diode LED on each of the pixel circuit layers PCL illustrated in FIG. 9 may correspond to one of the first to third light-emitting diodes LED1, LED2, and LED3 illustrated in FIG. 7.

The pixel circuit layers PCL may each include an inorganic insulating stack IIL, a pixel circuit PC, and an organic insulating layer OIL. For convenience of explanation, one of the pixel circuit layers PCL respectively disposed in the two adjacent first regions 11 is referred to as a first pixel circuit layer PCL1 and the other thereof is referred to as a second pixel circuit layer PCL2.

The first pixel circuit layer PCL1 and the second pixel circuit layer PCL2 may each be disposed on the base layer 400. The first pixel circuit layer PCL1 and the second pixel circuit layer PCL2 may each be disposed on a first surface (e.g., an upper surface) of the base layer 400.

The base layer 400 may absorb stress occurring when the display panel 10 is stretched. The base layer 400 may include an elastic polymer. The base layer 400 may include thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, PDMS (polydimethylsiloxane), and/or Ecoflex™ (Ecoflex™ being a registered trademark of Smooth-On, Inc.).

The first pixel circuit layer PCL1 and the second pixel circuit layer PCL2 may each include an inorganic insulating stack IIL, a pixel circuit PC, and an organic insulating layer OIL. The inorganic insulating stack IIL may include a buffer layer 111, a gate insulating layer 113, a first interlayer insulating layer 115, and a second interlayer insulating layer 117. The organic insulating layer OIL may include a first organic insulating layer 121 and a second organic insulating layer 123.

The first pixel circuit layer PCL1 and the second pixel circuit layer PCL2 may be spaced (e.g., spaced apart) from each other. The expression that the first pixel circuit layer PCL1 and the second pixel circuit layer PCL2 are spaced (e.g., spaced) apart from each other means that the inorganic insulating stack IIL, the pixel circuit PC, and the organic insulating layer OIL of the first pixel circuit layer PCL1 are respectively spaced (e.g., spaced apart) from the inorganic insulating stack IIL, the pixel circuit PC, and the organic insulating layer OIL of the second pixel circuit layer PCL2.

The inorganic insulating stack IIL may be disposed in the first region 11 and may not be disposed in the second region 12. In a plan view, the inorganic insulating stacks IIL disposed in the first regions 11 may be spaced (e.g., spaced apart) from each other. For example, the buffer layer 111, the gate insulating layer 113, the first interlayer insulating layer 115, and the second interlayer insulating layer 117 of the first pixel circuit layer PCL1 may be respectively separated and spaced (e.g., spaced apart) from the buffer layer 111, the gate insulating layer 113, the first interlayer insulating layer 115, and the second interlayer insulating layer 117 of the second pixel circuit layer PCL2.

Similarly, the organic insulating layer OIL may be disposed in the first region 11 and may not be disposed in the second region 12. For example, the first organic insulating layer 121 and the second organic insulating layer 123 of the first pixel circuit layer PCL1 may be respectively separated and spaced (e.g., spaced apart) from the first organic insulating layer 121 and the second organic insulating layer 123 of the second pixel circuit layer PCL2.

As illustrated in FIG. 9, the buffer layer 111 may be disposed on the base layer 400 and the pixel circuit PC may be disposed on the buffer layer 111. The buffer layer 111 may include an inorganic insulating material, such as silicon oxide, silicon nitride, and/or silicon oxynitride.

A thin-film transistor TFT of the pixel circuit PC may include a semiconductor layer Act, a gate electrode GE, a source electrode SE, and a drain electrode DE. FIG. 9 illustrates a top gate type in which the gate electrode GE is disposed on the semiconductor layer Act with a gate insulating layer 113 therebetween. However, according to another embodiment, the thin-film transistor TFT may be a bottom gate type.

The semiconductor layer Act may include polysilicon. Alternatively, the semiconductor layer Act may include amorphous silicon, an oxide semiconductor, and/or an organic semiconductor. The gate electrode GE may include a metal thin-film including a low-resistance metal material. The gate electrode GE may include a conductive material including molybdenum (Mo), aluminum (Al), copper (Cu), titanium (Ti), and/or the like, and may include a single layer or layers including the conductive material described above. For example, the gate electrode GE may include a metal thin-film including a triple layer having a titanium (Ti)/aluminum (Al)/titanium (Ti) structure.

The gate insulating layer 113 between the semiconductor layer Act and the gate electrode GE may include an inorganic insulating material, such as silicon oxide, nitrogen oxide, silicon oxynitride, aluminum oxide, and/or titanium oxide. The gate insulating layer 113 may include a single layer or layers including the inorganic insulating material described above.

The source electrode SE and the drain electrode DE may be disposed on (or at) the same layer, for example, a second interlayer insulating layer 117, and may include the same material. The source electrode SE and the drain electrode DE may each include a metal thin-film including a low-resistance metal material. The source electrode SE and the drain electrode DE may each include a conductive material including molybdenum (Mo), aluminum (Al), copper (Cu), titanium (Ti), and/or the like and may each include a single layer or layers including the conductive material described above. For example, like the gate electrode GE, the source electrode SE and the drain electrode DE may each include a metal thin-film including a triple layer having a titanium (Ti)/aluminum (Al)/titanium (Ti) structure. The second interlayer insulating layer 117 may include an inorganic insulating material, such as silicon oxide, nitrogen oxide, silicon oxynitride, aluminum oxide, and/or titanium oxide, and may be a single layer or layers including the inorganic insulating material described above.

The storage capacitor Cst may include a first electrode CE1 and a second electrode CE2 that overlap each other with the first interlayer insulating layer 115 therebetween. The storage capacitor Cst may overlap the thin-film transistor TFT. In this regard, FIG. 9 illustrates that the gate electrode GE of the thin-film transistor TFT is the first electrode CE1 of the storage capacitor Cst. In another embodiment, the storage capacitor Cst may not overlap the thin-film transistor TFT. The storage capacitor Cst may be covered by the second interlayer insulating layer 117.

The first interlayer insulating layer 115 may be disposed between the gate insulating layer 113 and the second interlayer insulating layer 117. The first interlayer insulating layer 115 and the second interlayer insulating layer 117 may each include an inorganic insulating material, such as silicon oxide, nitrogen oxide, silicon oxynitride, aluminum oxide, and/or titanium oxide, and may each be a single layer or layers including the inorganic insulating material described above.

The second electrode CE2 of the storage capacitor Cst may include a conductive material and may include a single layer or layers. The second electrode CE2 may include a metal thin-film including a low-resistance metal material. The second electrode CE2 may include a conductive material including molybdenum (Mo), aluminum (Al), copper (Cu), titanium (Ti), and/or the like, and may include a single layer or layers including the conductive material described above. For example, the second electrode CE2 may include a metal thin-film including a triple layer having a titanium (Ti)/aluminum (Al)/titanium (Ti) structure.

The first organic insulating layer 121 may be disposed on the second interlayer insulating layer 117. The second organic insulating layer 123 may be disposed on the first organic insulating layer 121. A connection electrode CM and a second voltage line VSSL may be disposed on the first organic insulating layer 121. The connection electrode CM may electrically connect the pixel circuit PC to a first electrode pad 241. The second voltage line VSSL may be electrically connected to a second electrode pad 242.

The connection electrode CM and the second voltage line VSSL may each include a metal thin-film including a low-resistance metal material. The connection electrode CM and the second voltage line VSSL may each include a conductive material including molybdenum (Mo), aluminum (Al), copper (Cu), titanium (Ti), and/or the like, and may each include a single layer or layers including the conductive material described above. For example, the connection electrode CM and the second voltage line VSSL may each include a metal thin-film including a triple layer having a titanium (Ti)/aluminum (Al)/titanium (Ti) structure.

The first electrode pad 241 and the second electrode pad 242 may be disposed on the second organic insulating layer 123. The first electrode pad 241 may be electrically connected to the thin-film transistor TFT through the connection electrode CM disposed between the first organic insulating layer 121 and the second organic insulating layer 123.

The light-emitting diode LED on the first electrode pad 241 and the second electrode pad 242 may be the same as the light-emitting diode LED described above with reference to FIG. 6A. In another embodiment, the light-emitting diode LED may have structures as illustrated in FIG. 6B-6E. One surface of the light-emitting diode LED may be covered by a protective layer 240 including an organic insulating material or including an inorganic insulating material and an organic insulating material.

The lines L described above with reference to FIG. 7 may be electrically connected to the pixel circuits PC of the pixel circuit layer PCL. In this regard, FIG. 9 illustrates that a line (hereinafter referred to as a first line L1) disposed in the first region 11 from among the lines L is electrically connected to the pixel circuit PC of the first pixel circuit layer PCL1 and a line (hereinafter referred to as a second line L2) disposed in another first region 11 is electrically connected to the second pixel circuit layer PCL2.

The first line L1 may be a signal line or a voltage line electrically connected to the pixel circuit PC of the first pixel circuit layer PCL1. The second line L2 may be a signal line or a voltage line electrically connected to the pixel circuit PC of the second pixel circuit layer PCL2. In one or more embodiments, the first line L1 and the second line L2 may be the gate line, the data line DL, the first initialization voltage line VIL1, the second initialization voltage line VIL2, the sustain voltage line VSL, the first voltage line VDDL, or the second voltage line VSSL, which have been described above with reference to FIG. 5A-5C.

Each of the first line L1 and the second line L2 may be disposed on the interlayer insulating layer 117 and may extend over the connection line WL. A portion of the first line L1 may be disposed on the corresponding second interlayer insulating layer 117. Another portion of the first line L1 may extend over the connection line WL through the inorganic insulation stack IIL and may be in direct contact with the connection line WL. Along a direction (e.g., the +z direction) perpendicular to the upper surface of the base layer 400, the aforementioned portion of the first line L1 may be disposed between the corresponding second interlayer insulating layer 117 and the corresponding first organic insulating layer 121, and the aforementioned other portion of the first line L1 may be disposed between the connection line WL and the corresponding first organic insulating layer 121. A portion of the second line L2 may be disposed on the corresponding second interlayer insulating layer 117 and another portion of the second line L2 may extend over the connection line WL and may be in direct contact with the connection line WL. Along a direction (e.g., the +z direction) perpendicular to the upper surface of the base layer 400, the aforementioned portion of the second line L2 may be disposed between the corresponding second interlayer insulating layer 117 and the corresponding first organic insulating layer 121, and the aforementioned other portion of the second line L2 may be disposed between the connection line WL and the corresponding first organic insulating layer 121.

The inorganic insulating stack IIL having an isolated shape in a plan view may form a step with respect to the upper surface of the base layer 400. In one or more embodiments, as illustrated in FIG. 9, the organic insulating layer OIL may further include a third organic insulating layer 119 disposed to cover the side surface of the inorganic insulating stack IIL. In a plan view, the third organic insulating layer 119 may have a closed loop shape so as to cover the side surface of the inorganic insulating stack IIL. In other words, in a plan view, the third organic insulating layer 119 may have a frame shape.

The first line L1 and the second line L2 may extend over the connection line WL through the upper surface of the corresponding third organic insulating layer 119. In the cross-sectional view of FIG. 9, a first thickness t1 of a first portion of the base layer 400 that overlaps the connection line WL may be less than a thickness of another portion of the base layer 400 that does not overlap the connection line WL. For example, the first thickness t1 of the first portion of the base layer 400 that overlaps the connection line WL may be less than a second thickness t2 of a second portion of the base layer 400 that overlaps the pixel circuit PC or the inorganic insulating stack IIL of the first pixel circuit layer PCL1. The first thickness t1 of the first portion of the base layer 400 that overlaps the connection line WL may be less than a third thickness t3 of the third portion of the base layer 400 that overlaps the pixel circuit PC or the inorganic insulating stack IIL of the second pixel circuit layer PCL2.

The base layer 400 may include a first surface (e.g., an upper surface) facing the first pixel circuit layer PCL1 and the second pixel circuit layer PCL2 and a second surface (e.g., a lower surface) opposite the first surface. The base layer 400 may include a recess (or a concave portion) 400RC concave with respect to the first surface. The connection line WL may be present in the recess 400RC. For example, the connection line WL may fill the recess 400RC. In one or more embodiments, the volume of the connection line WL may be substantially equal to the volume of the recess 400RC. Because the connection line WL has a structure embedded in the base layer 400, the base layer 400 may absorb stress that may concentrate on the connection line WL when the display panel 10 is stretched.

The connection line WL may include a first surface (e.g., a lower surface) facing the base layer 400 and a second surface (e.g., an upper surface) opposite the first surface. The second surface (e.g., the upper surface) of the connection line WL may be disposed on (e.g., at) the same surface as the first surface (e.g., the upper surface) of the base layer 400. The first surface (e.g., the lower surface) of the connection line WL may be disposed between the first surface (e.g., the upper surface) of the base layer 400 and the second surface (e.g., the lower surface) of the base layer 400.

The inorganic insulating stack IIL and the organic insulating layer OL, which overlap each other, may have different widths. For example, the first organic insulating layer 121 corresponding to the first pixel circuit layer PCL1 may extend toward a first connection point of the first line L1 and the connection line WL through the side surface of the inorganic insulating stack IIL, and the first organic insulating layer 121 corresponding to the second pixel circuit layer PCL2 may extend toward a second connection point of the second line L2 and the connection line WL through the side surface of the inorganic insulating stack IIL.

The first connection point of the first line L1 and the connection line WL and the second connection point of the second line L2 and the connection line WL may be disposed between the inorganic insulating stack IIL of the first pixel circuit layer PCL1 and the inorganic insulating stack IIL of the second pixel circuit layer PCL2. The first connection point of the first line L1 and the connection line WL does not overlap the inorganic insulating stack IIL of the first pixel circuit layer PCL1, and the second connection point of the second line L2 and the connection line WL does not overlap the inorganic insulating stack IIL of the second pixel circuit layer PCL2.

The first organic insulating layer 121 corresponding to the first pixel circuit layer PCL1 may overlap the first connection point of the first line L1 and the connection line WL, and the first organic insulating layer 121 corresponding to the second pixel circuit layer PCL2 may overlap the second connection point of the second line L2 and the connection line WL. The first organic insulating layer 121 of the first pixel circuit layer PCL1 and the first organic insulating layer 121 of the second pixel circuit layer PCL2 may be in contact with the upper surface of the connection line WL.

The light-emitting diodes LED may be disposed on the corresponding pixel circuit layers PCL. For example, the light-emitting diode LED electrically connected to the pixel circuit PC of the first pixel circuit layer PCL1 may be disposed on the corresponding first pixel circuit layer PCL1, and the light-emitting diode LED electrically connected to the pixel circuit PC of the second pixel circuit layer PCL2 may be disposed on the corresponding second pixel circuit layer PCL2.

The protective layer 300 may be disposed on the light-emitting diode LED and the connection line WL. The protective layer 300 may cover the light-emitting diode LED and the connection line WL. The protective layer 300 may absorb stress that may be transmitted to the light-emitting diode LED and the connection line WL when the display panel 10 is stretched, and may planarize the upper surface of the display panel 10. The protective layer 300 may include an elastic polymer. For example, the protective layer 300 may include thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, PDMS(polydimethylsiloxane), and/or Ecoflex™ (Ecoflex™ being a registered trademark of Smooth-On, Inc.).

The protective layer 300 may be in direct contact with the upper surface of the connection line WL and may be in direct contact with a portion of the upper surface of the base layer 400. In one or more embodiments, when the material of the protective layer 300 is the same as the material of the base layer 400, the bonding strength between the protective layer 300 and the base layer 400 may be increased, and thus, the sealing of the display panel 10 may be maintained more effectively. In one or more embodiments, as shown in FIG. 9, a gate line GL (e.g., including the scan signal line GWL, the bypass control line GBL, the initialization control line GIL, and/or the emission control line EML) may be disposed between the second interlayer insulating layer 117 and the first organic insulating layer 121.

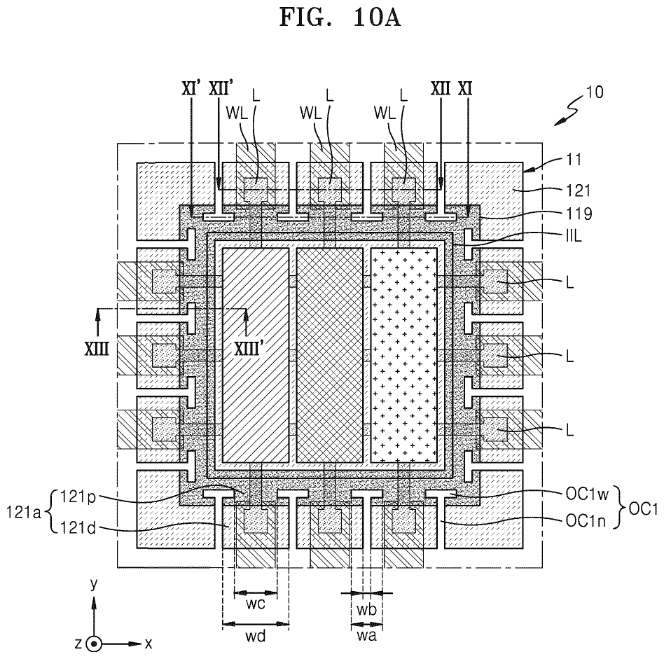

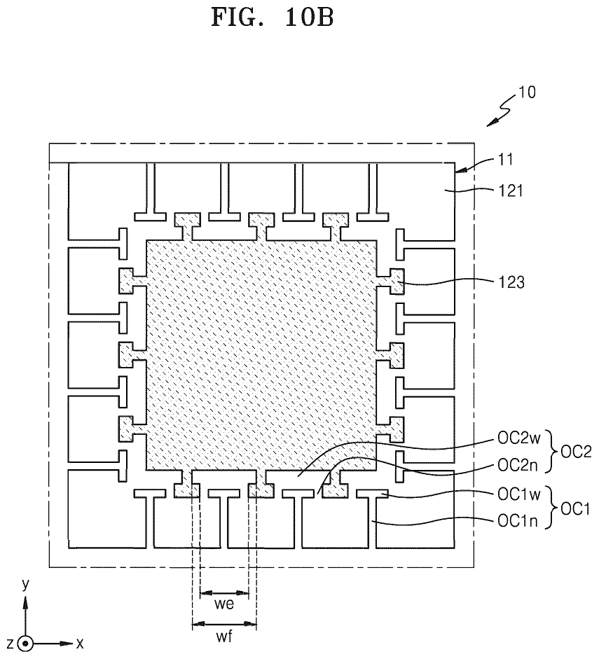

FIG. 10A is a plan view illustrating the first organic insulating layer 121, the third organic insulating layer 119, the inorganic insulating stack IIL, the line L, and the connection line WL, which are disposed in the first region 11 of the display panel 10 according to one or more embodiments.

Referring to FIG. 10A, the first organic insulating layer 121 may overlap the third organic insulating layer 119 and the inorganic insulating stack IIL. In a plan view, the third organic insulating layer 119 may have a closed loop shape (or a frame shape) overlapping and/or surrounding the edge of the inorganic insulating stack IIL.

The first organic insulating layer 121 may include first grooves OC1 spaced (e.g., spaced apart) from each other along the edge (e.g., an edge periphery or an edge circumference) thereof. In a plan view, the first grooves OC1 may each include a first portion OC1n having a first width wb and a second portion OC1w spatially connected to the first portion OC1n and having a second width wa. The second width wa may be greater than the first width wb.

The first portion OC1n may extend toward the edge of the first organic insulating layer 121 and may be spatially connected to a space outside the first organic insulating layer 121. The first portion OC1n may be disposed between the edge of the first organic insulating layer 121 and the second portion OC1w. In other words, the second portion OC1w may be disposed between the edge of the inorganic insulating stack IIL and the first portion OC1n. A portion of the protective layer 300 described above with reference to FIG. 9 may be disposed in the first groove OC1. The shape of the first groove OC1 in a plan view is a kind of anchor-like (e.g., “T” shaped) structure, which may increase the bonding strength with the protective layer 300. Thus, when the display panel 10 is stretched, the separation of the protective layer 300 may be prevented.

The first grooves OC1 may be spaced (e.g., spaced apart) from each other and the lines L may be disposed between two adjacent first grooves OC1 and may overlap a portion of the first organic insulating layer 121. As illustrated in FIG. 10A, the line L and the connection line WL may be in direct contact between the two adjacent first grooves OC1.

A distal end 121d of a portion 121a of the first organic insulating layer 121 between the two adjacent first grooves OC1 may be disposed between the first portions OC1n of the first grooves OC1, and a proximal end 121p of the portion 121a of the first organic insulating layer 121 may be disposed between the second portions OC1w of the first grooves OC1. A width wd of the distal end 121d of the portion 121a of the first organic insulating layer 121 may be greater than a width wc of the proximal end 121p of the portion 121a of the first organic insulating layer 121.

FIG. 10B is a plan view illustrating the first organic insulating layer 121 and the second organic insulating layer 123, which are disposed in the first region of the display panel, according to one or more embodiments.

Referring to FIG. 10B, the second organic insulating layer 123 may overlap the first organic insulating layer 121 and may have a width that is relatively less than a width of the first organic insulating layer 121. The second organic insulating layer 123 may include second grooves OC2 spaced (e.g., spaced apart) from each other along the edge (e.g., an edge periphery or an edge circumference) thereof. In a plan view, the second grooves OC2 may each include a first portion OC2n having a first width we and a second portion OC2w spatially connected to the first portion OC2n and having a second width wf. The second width wf may be greater than the first width we.

The first portion OC2n of the second groove OC2 may extend toward the edge of the second organic insulating layer 123. The first portion OC2n of the second groove OC2 may be disposed between the edge of the second organic insulating layer 123 and the second portion OC2w. A portion of the protective layer 300 described above with reference to FIG. 9 may be disposed in the second groove OC2. The shape of the second groove OC2 in a plan view is a kind of anchor-like structure, which may increase the bonding strength with the protective layer 300. Thus, when the display panel 10 is stretched, the separation of the protective layer 300 may be prevented.

A distal end of a portion of the second organic insulating layer 123 between two adjacent second grooves OC2 may be disposed between the first portions OC2n of the second grooves OC2, and a proximal end of the portion of the second organic insulating layer 123 may be disposed between the second portions OC2w of the second grooves OC2. A width of the distal end of the portion of the second organic insulating layer 123 may be greater than a width of the proximal end thereof.

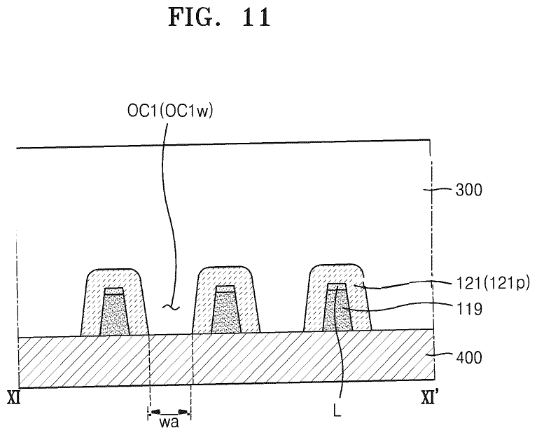

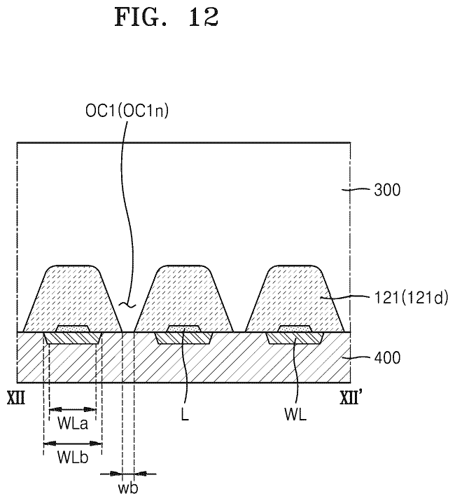

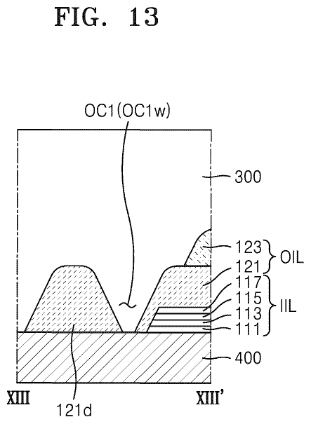

FIG. 11 is a cross-sectional view of the display panel of FIG. 10A taken along the line XI-XI′ of FIG. 10A, FIG. 12 is a cross-sectional view of the display panel of FIG. 10A taken along the line XII-XII′ of FIG. 10A, and FIG. 13 is a cross-sectional view of the display panel of FIG. 10A taken along the line XIII-XIII′ of FIG. 10A.

Referring to FIG. 11, a stacked structure of a portion of the third organic insulating layer 119 and a portion (e.g., the proximal end 121p) of the first organic insulating layer 121 may be disposed on both sides of the second portion OC1w of the first groove OC1. A portion of each of the lines L disposed on both sides of the second portion OC1w may be disposed between the third organic insulating layer 119 and the first organic insulating layer 121. A portion of the protective layer 300 may be disposed in the second portion OC1w of the first groove OC1 and may be in direct contact with the side surface of the portion of the first organic insulating layer 121 defining the second portion OC1w of the first groove OC1 and the upper surface of the base layer 400.

Referring to FIG. 12, the line L and the connection line WL may be in direct contact with each other on both sides of the first portion OC1n of the first groove OC1, and the contact area (e.g., the connection point) of the line L and the connection line WL may be covered by a portion (e.g., the distal end 121d) of the first organic insulating layer 121. A width of the line L may be less than a width of the connection line WL. The connection line WL may include a first surface (an upper surface) in contact with the line L and a second surface (a lower surface) opposite to the first surface. A width of the first surface (the upper surface) of the connection line WL may be different from a width of the second surface (the lower surface) of the connection line WL. For example, a width WLb of the first surface (the upper surface) of the connection line WL may be greater than a width WLa of the second surface (the lower surface) of the connection line WL. In a cross-sectional view, the connection line WL may have an inverted trapezoidal shape. A portion of the protective layer 300 may be disposed in the first portion OC1n of the first groove OC1 and may be in direct contact with the side surface of the portion of the first organic insulating layer 121 defining the first portion OC1n of the first groove OC1 and the upper surface of the base layer 400.

Referring to FIG. 13, a portion of the second portion OC1w of the first groove OC1 may be disposed between the edge of the inorganic insulating stack IIL and a portion (e.g., the distal end 121d) of the first organic insulating layer 121. A portion of the protective layer 300 may be disposed in the first portion OC1n and a portion of the second portion OC1w of the first groove OC1 and may be in direct contact with the side surface of the portion of the first organic insulating layer 121 and the upper surface of the base layer 400.

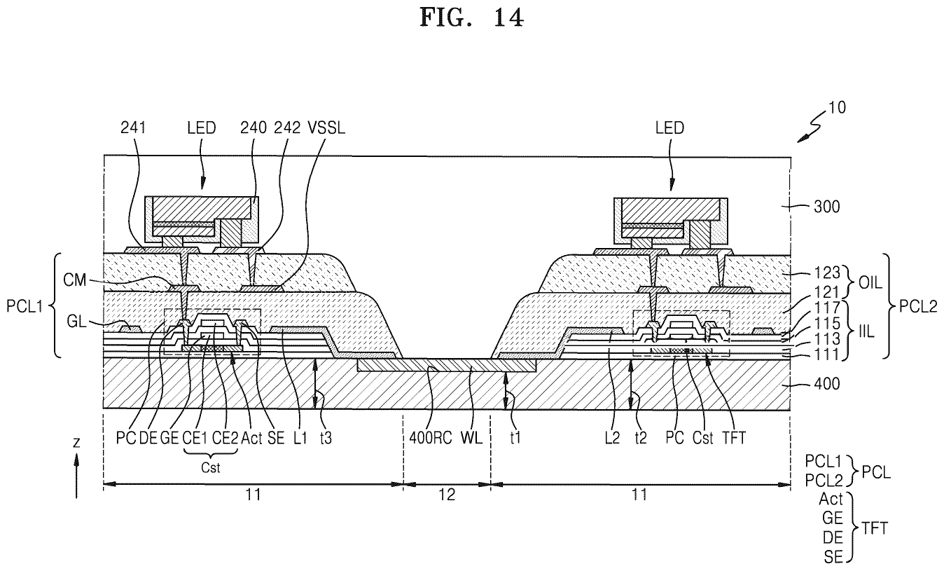

FIG. 14 is a cross-sectional view illustrating a portion of a display panel 10 according to one or more embodiments.

The display panel 10 illustrated in FIG. 14 does not include the third organic insulating layer 119, unlike the embodiment described above with reference to FIG. 9. Because the structure of the display panel 10 according to the embodiment of FIG. 14 is substantially identical to the structure described with reference to FIG. 9, the following description is given focusing on differences.

Referring to FIG. 14, a first line L1 may extend over a connection line WL while being in contact with a side surface of a corresponding inorganic insulating stack IIL, and a second line L2 may extend over the connection line WL while being in contact with a side surface of a corresponding inorganic insulating stack IIL. A width of a first organic insulating layer 121 of a first pixel circuit layer PCL1 may be greater than a width of the inorganic insulating stack IIL. The first organic insulating layer 121 may cover a first connection point of the first line L1 and the connection line WL. Similarly, a width of a first organic insulating layer 121 of a second pixel circuit layer PCL2 may be greater than a width of the inorganic insulating stack IIL. The first organic insulating layer 121 may cover a second connection point of the second line L2 and the connection line WL.

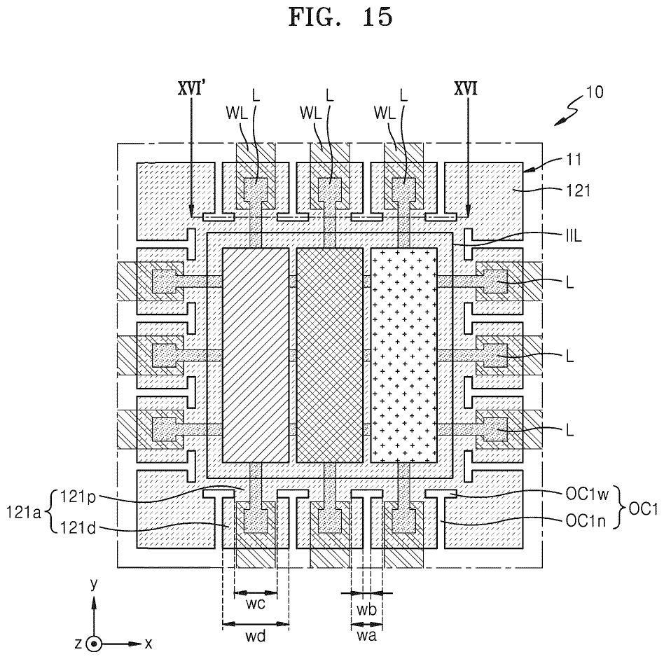

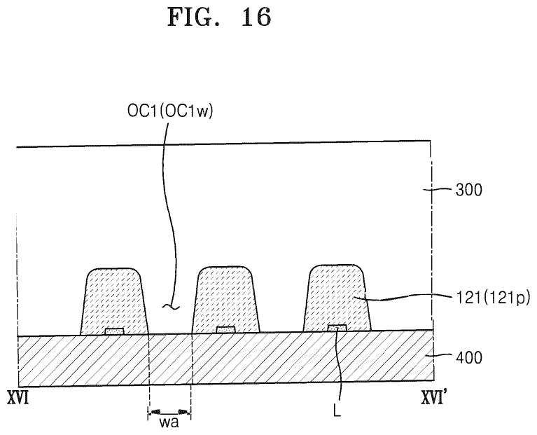

FIG. 15 is a plan view illustrating a first organic insulating layer 121, an inorganic insulating stack IIL, a line L, and a connection line WL, which are disposed in a first region 11 of a display panel 10, according to one or more embodiments and FIG. 16 is a cross-sectional view of the display panel 10 of FIG. 15 taken along the line XVI-XVI′ of FIG. 15.

Referring to FIG. 15, the first organic insulating layer 121 may overlap the inorganic insulating stack IIL. The first organic insulating layer 121 may include first grooves OC1 spaced (e.g., spaced apart) from each other along the edge (e.g., an edge periphery or an edge circumference) thereof. In a plan view, the first grooves OC1 may each include a first portion OC1n having a first width wb and a second portion OC1w spatially connected to the first portion OC1n and having a second width wa. The second width wa may be greater than the first width wb. A specific shape of the first groove OC1 is the same as described above with reference to FIG. 10A.

A distal end 121d of a portion 121a of the first organic insulating layer 121 between the two adjacent first grooves OC1 may be disposed between the first portions OC1n of the first grooves OC1, and a proximal end 121p of the portion 121a of the first organic insulating layer 121 may be disposed between the second portions OC1w of the first grooves OC1. A width wd of the distal end 121d of the portion 121a of the first organic insulating layer 121 may be greater than a width wc of the proximal end 121p of the portion 121a of the first organic insulating layer 121.

Because the display panel according to the embodiment illustrated in FIG. 15 does not include the third organic insulating layer 119, the line L may be in direct contact with the upper surface of the base layer 400 on both sides of the second portion OC1w of the first groove OC1, as illustrated in FIG. 16. A portion (e.g., the proximal end 121p) of the first organic insulating layer 121 may be disposed between the second portions OC1w of the first groove OC1.

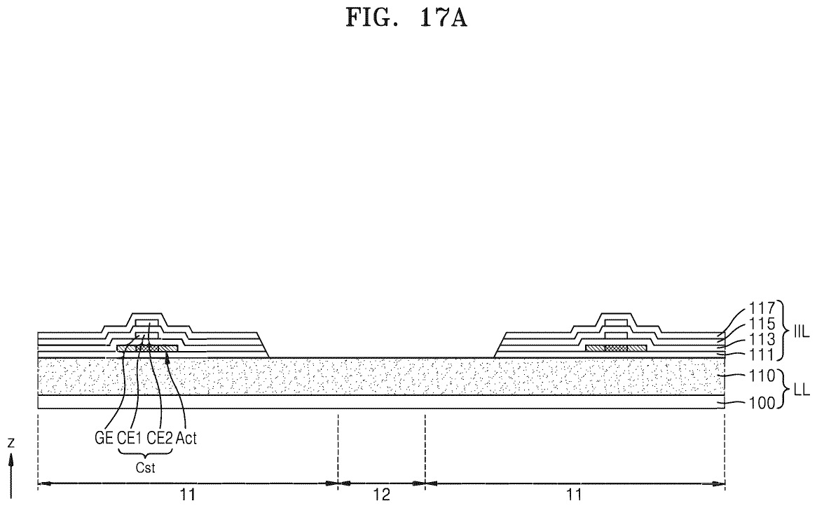

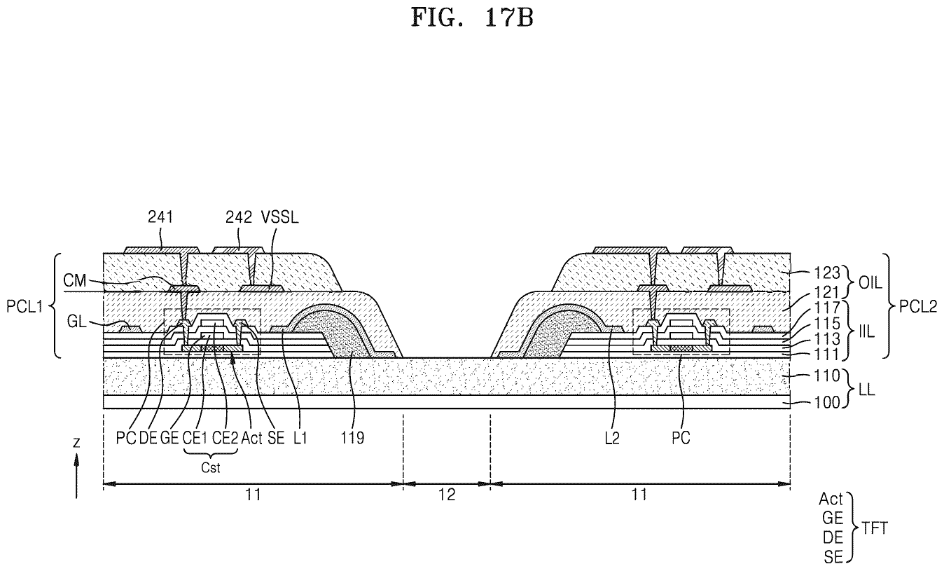

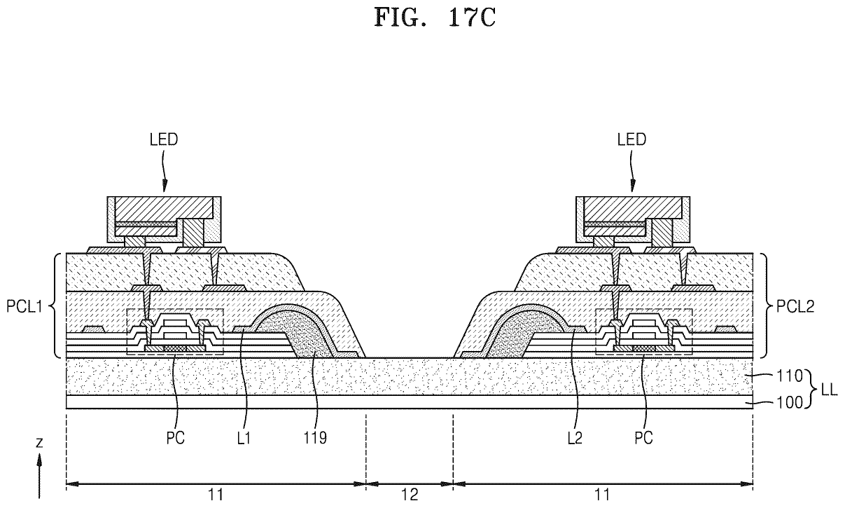

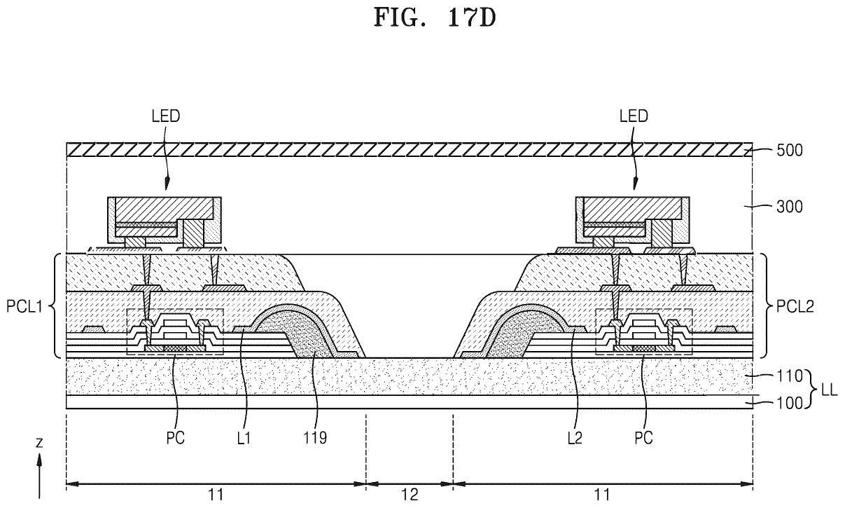

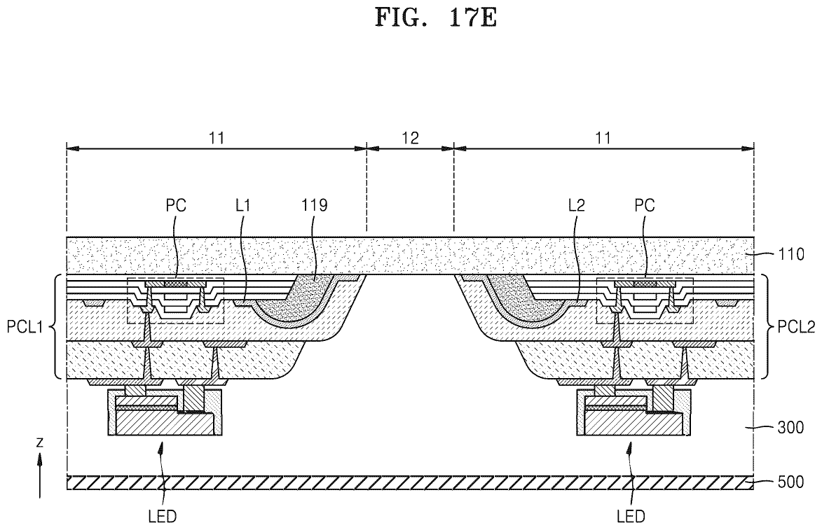

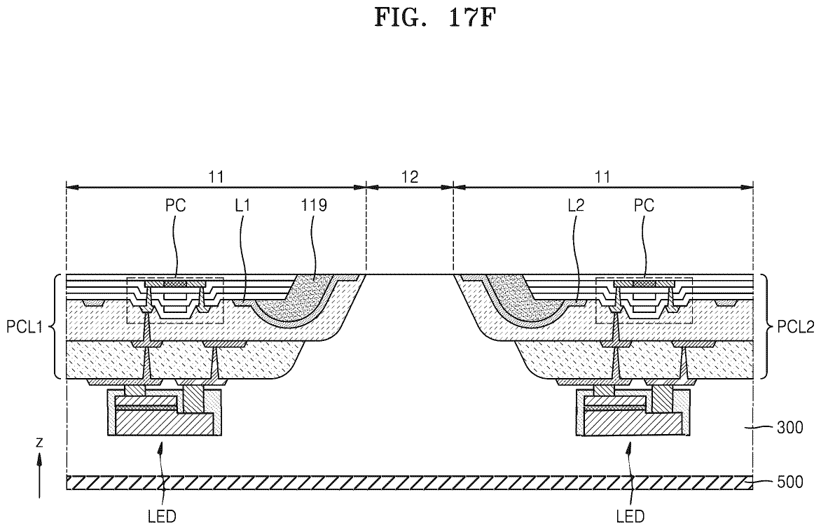

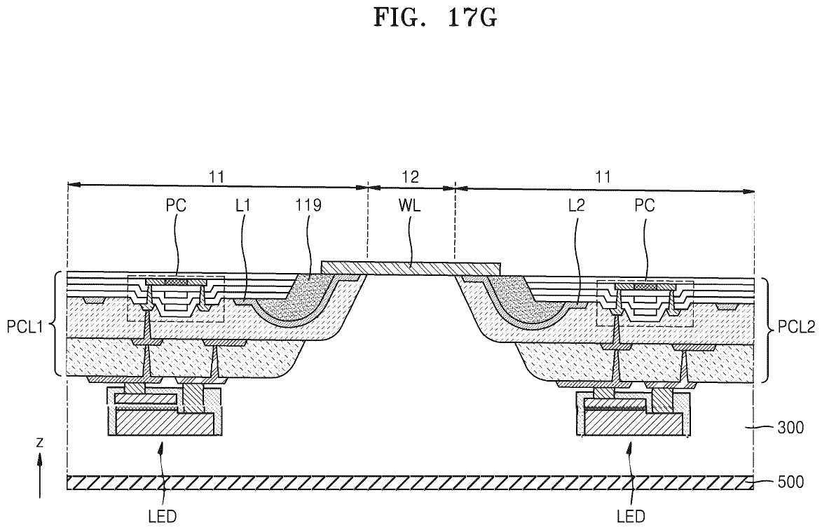

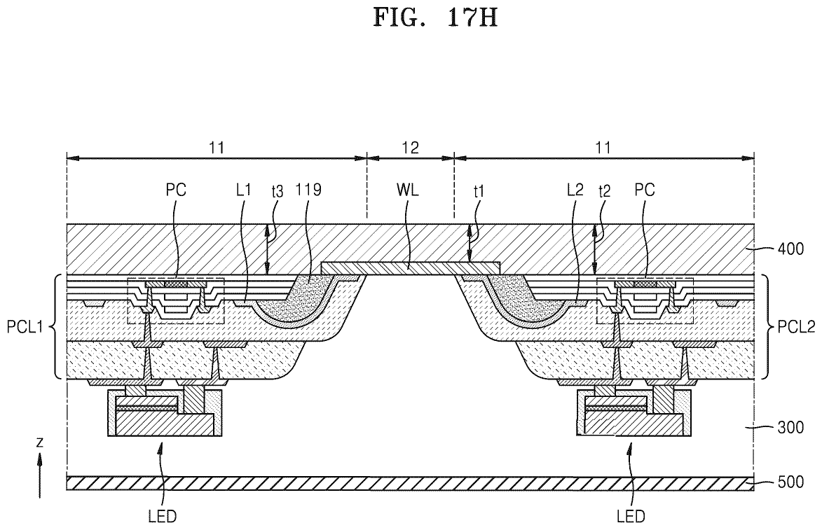

FIG. 17A-17H are cross-sectional views schematically illustrating a process of manufacturing a display panel, according to an embodiment.

Referring to FIG. 17A, a carrier layer LL may be prepared. In one or more embodiments, the carrier layer LL may include a substrate 100 and a resin layer 110 disposed on the substrate 100. The substrate 100 may be a rigid substrate. For example, the substrate 100 may be a transparent glass substrate including SiO₂ as a main component, or may be a substrate including a polymer resin material, such as reinforced plastic. The resin layer 110 may include a polymer resin. For example, the resin layer 110 may include polyethersulfone, polyacrylate, polyether imide, polyethylene naphthalate, polyethylene terephthalate, polyphenylene sulfide, polyarylate, polyimide, polycarbonate, and/or cellulose acetate propionate. In one or more embodiments, a thickness of the resin layer 110 may be greater than a thickness of the substrate 100.

An inorganic insulating stack IIL, a storage capacitor Cst, and a portion of a thin-film transistor (see TFT of FIG. 9) may be formed on the carrier layer LL. For example, a buffer layer 111, a semiconductor layer Act, a gate insulating layer 113, a gate electrode GE, a first interlayer insulating layer 115, a second electrode CE2 of the storage capacitor Cst, and a second interlayer insulating layer 117 may be formed on the carrier layer LL.

The inorganic insulating stack IIL may be disposed only in a first region 11 and may not be disposed in a second region 12. For example, a portion of the inorganic insulating stack IIL overlapping the second region 12 may be removed by an etching process.

Referring to FIG. 17B, a third organic insulating layer 119 may be formed on the second interlayer insulating layer 117. The third organic insulating layer 119 may cover the side surface of the inorganic insulating stack IIL. A source electrode SE and a drain electrode DE may be formed on the second interlayer insulating layer 117.

A first line L1 and a second line L2 may be formed. The first line L1 may be disposed on the corresponding second interlayer insulating layer 117 and may extend over the upper surface of the resin layer 110 through the upper surface of the third organic insulating layer 119. The second line L2 may be disposed on the corresponding second interlayer insulating layer 117 and may extend over the first surface of the resin layer 110 (e.g., the surface facing the buffer layer 111) through the upper surface of the third organic insulating layer 119.

A first organic insulating layer 121 may be formed on a pixel circuit PC, and a connection electrode CM and a second voltage line VSSL may be formed on the first organic insulating layer 121. A second organic insulating layer 123 may be formed on the first organic insulating layer 121 covering the connection electrode CM and the second voltage line VSSL, and a first electrode pad 241 and a second electrode pad 242 may be formed on the second organic insulating layer 123.

Although FIG. 17B illustrates a structure in which the third organic insulating layer 119 is formed, the present disclosure is not limited thereto. In another embodiment, as illustrated in FIG. 14, the third organic insulating layer 119 may not be formed. In this case, each of the first line L1 and the second line L2 may extend over the first surface of the resin layer 110 while being in direct contact with the side surface of the corresponding inorganic insulating stack IIL.

Referring to FIG. 17C, light-emitting diodes LED may be respectively formed on the first pixel circuit layer PCL1 and the second pixel circuit layer PCL2 described above with reference to FIG. 17B. The light-emitting diodes LED may each be an inorganic light-emitting diode.

Referring to FIG. 17D, a protective layer 300 may be formed on the light-emitting diodes LED. The protective layer 300 may include the same material as the material described above with reference to FIG. 9. During the process, the protective layer 300 may be in direct contact with the resin layer 110. The protective layer 300 may be formed by depositing a material (e.g., an elastic polymer) constituting the protective layer 300 and then curing the deposited material. The curing process may utilize heat or light, such as ultraviolet (UV) light.

A carrier film 500 may be formed on the protective layer 300. In one or more embodiments, an adhesive layer may be further disposed between the protective layer 300 and the carrier film 500. The carrier film 500 may protect the protective layer 300 from scratch or damage that occurs during the process. For example, the carrier film 500 may include an insulating material.

Referring to FIG. 17E, after reversing the structure obtained after the process of FIG. 17D, the substrate 100 may be removed from the resin layer 110. By irradiating a laser onto the other surface of the substrate 100 opposite to one surface of the substrate 100 that is in contact with the resin layer 110, the bonding strength between the substrate 100 and the resin layer 110 may be weakened. Accordingly, the substrate 100 may be separated and removed from the resin layer 110. However, this is only an example and the method of removing the substrate 100 may be variously changed.

Referring to FIG. 17F, the resin layer 110 may be removed. The resin layer 110 may be removed by a dry etching process. As the resin layer 110 is removed, one surface of each of the first pixel circuit layer PCL1 and the second pixel circuit layer PC2 (e.g., the surface located opposite to the surface facing the light-emitting diode LED) may be exposed. For example, one surface of the inorganic insulating stack IIL of each of the first pixel circuit layer PCL1 and the second pixel circuit layer PCL2 (e.g., the surface located opposite to the surface facing the first organic insulating layer 121), one surface of a portion of the first organic insulating layer 121 of each of the first pixel circuit layer PCL1 and the second pixel circuit layer PCL2, and one surface of a portion of each of the first line L1 and the second line L2 may be exposed. One surface of the inorganic insulating stack IIL, one surface of a portion of the first organic insulating layer 121, and one surface of a portion of each of the first line L1 and the second line L2 may be disposed on (or at) the same plane.

Referring to FIG. 17G, a connection line WL may be formed. The connection line WL may be in direct contact with the exposed portion of the first line L1 and the exposed portion of the second line L2. The connection line WL may be disposed in the second region 12 between two adjacent first regions 11 and may extend from one of the two adjacent first regions 11 toward the other thereof.

In one or more embodiments, the connection line WL may include a liquid metal or a conductive composite material including a metal nanostructure, elastic polymer, and/or elastomer. The connection line WL may be formed by a vacuum deposition process, a printing process, a coating process, and/or the like.

Referring to FIG. 17H, a base layer 400 may be formed on the connection line WL. The base layer 400 may be disposed to cover the connection line WL. The base layer 400 may include the same material as the material described above with reference to FIG. 9. The base layer 400 may support components of the display panel (see 10 of FIG. 9) and may absorb stress that may occur when the display panel (see 10 of FIG. 9) is stretched.

The structure of FIG. 17H may be reversed again as illustrated in FIG. 9. The display panel 10 as illustrated in FIG. 9 may be formed by removing the carrier film 500. The carrier film (see 500 of FIG. 17H) may be removed by using a peeling tape.

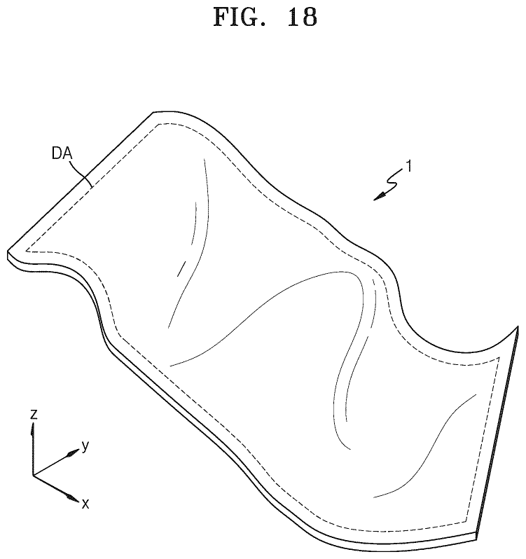

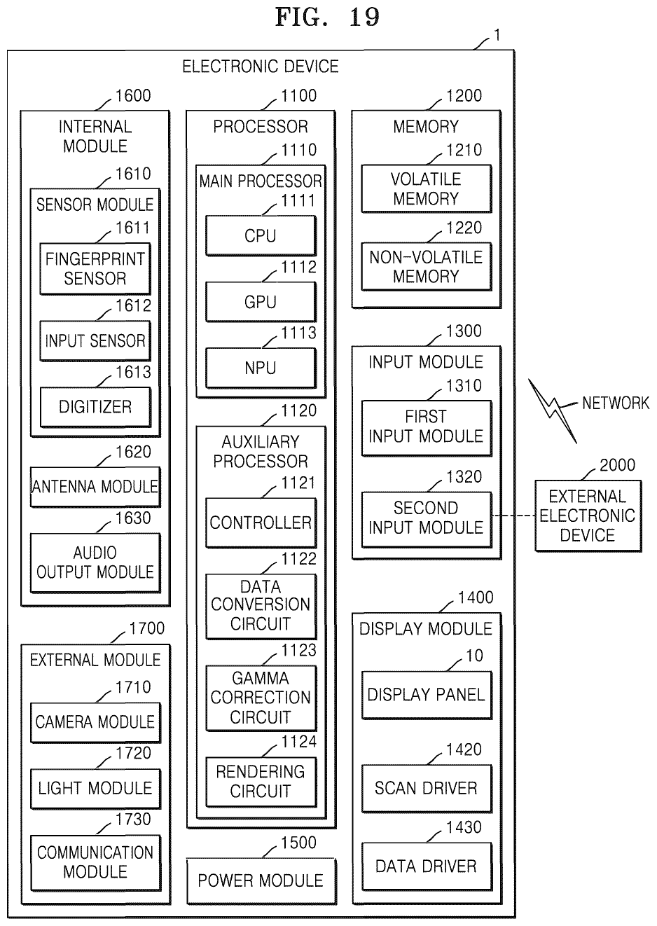

FIG. 18 is a perspective view schematically illustrating an electronic device 1 including a display panel, according to one or more embodiments and FIG. 19 is a block diagram illustrating an electronic device 1 including a display panel 10, according to one or more embodiments.

Referring to FIG. 18, the electronic device 1 may be freely transformed three-dimensionally and provide a three-dimensional image surface through a display area DA. The expression that the electronic device 1 is freely transformed three-dimensionally is distinguished from the operation of the electronic device having a rollable display panel, such as a case where only a portion of the display area is visible to the user and then the entire display area is visible to the user while the folded display area is unfolded (or a case where the entire unfolded display area is visible to the user and then only a portion of the display area is visible to the user while the display area is folded). The electronic device 1 according to one or more embodiments may be deformed such that the area of the entire display area DA increases or decreases again as the electronic device 1 is deformed in the x direction, the y direction, and/or the z direction.

Referring to FIG. 19, the electronic device 1 may include a processor 1100, a memory 1200, an input module 1300, a display module 1400, a power module 1500, an internal module 1600, and an external module 1700. According to one or more embodiments, at least one of the components described above may be omitted from the electronic device 1, or one or more other components may be added to the electronic device 1. In one or more embodiments, some components described above (e.g., the internal module 1600) may be integrated into another component (e.g., the display module 1400).

The processor 1100 may execute software to control at least one other component (e.g., a hardware or software component) of the electronic device 1 connected to the processor 1100 and perform various data processing or operations. According to one or more embodiments, as at least part of data processing or operations, the processor 1100 may store commands or data received from another component (e.g., the input module 1300, a sensor module 1610, or a communication module 1730) in a volatile memory 1210, process the commands or data stored in the volatile memory 1210, and store resulting data in a non-volatile memory 1220.

The processor 1100 may include a main processor 1110 and an auxiliary processor 1120. The main processor 1110 may include at least one of a central processing unit (CPU) 1111 or an application processor (AP). The main processor 1110 may further include at least one of a graphic processing unit (GPU) 1112, a communication processor (CP), or an image signal processor (ISP). The main processor 1110 may further include a neural processing unit (NPU) 1113. The NPU 1113 is a processor specialized in processing an artificial intelligence model. The artificial intelligence model may be generated through machine learning. The artificial intelligence model may include a plurality of artificial neural network layers. The artificial intelligence model may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but the present disclosure is not limited to the above example. The artificial intelligence model may additionally or alternatively include a software structure in addition to the hardware structure. At least two of the processing units and processors described above may be implemented as a single integrated configuration (e.g., a single chip), or the processing units and processors described above may be implemented as independent configurations (e.g., a plurality of chips).

The auxiliary processor 1120 may include a controller 1121. The controller 1121 may include an interface conversion circuit and a timing control circuit. The controller 1121 may receive an image signal from the main processor 1110, convert the data format of the image signal to match the interface specification with the display module 1400, and output the image data. The controller 1121 may output various control signals required to drive the display module 1400.

The auxiliary processor 1120 may further include a data processing circuit, such as a data conversion circuit 1122, a gamma correction circuit 1123, and/or a rendering circuit 1124. The data conversion circuit 1122 may receive image data from the controller 1121, compensate for the image data so that the image is displayed at a desired luminance according to characteristics of the electronic device 1 or a user's settings, or convert the image data so as to reduce power consumption or compensate for afterimages. The gamma correction circuit 1123 may convert image data or gamma reference voltages so that the image displayed on the electronic device 1 has desired gamma characteristics. The rendering circuit 1124 may receive image data from the controller 1121 and render the image data by taking into account the pixel layout of the display panel 10 applied to the electronic device 1. At least one of the data conversion circuit 1122, the gamma correction circuit 1123, or the rendering circuit 1124 may be integrated into another component (e.g., the main processor 1110 or the controller 1121). In one or more embodiments, the auxiliary processor 1120 may be integrated into a data driver 1430.

The memory 1200 may store various data used by at least one component of the electronic device 1 (e.g., the processor 1100 or the sensor module 1610) and input data or output data for commands related thereto. The memory 1200 may include at least one of the volatile memory 1210 or the non-volatile memory 1220.

The input module 1300 may receive commands or data to be used in the components of the electronic device 1 (e.g., the processor 1100, the sensor module 1610, or the audio output module 1630) from the outside of the electronic device 1 (e.g., a user or an external electronic device 2000).

The input module 1300 may include a first input module 1310 to which commands or data are input from the user and a second input module 1320 to which commands or data are input from the external electronic device 2000.

The first input module 1310 may include a microphone, a mouse, a keyboard, or a pen (e.g., a passive pen or an active pen). The first input module 1310 may include a touch input means or a mechanical input means, such as a button, a dome switch, a jog wheel, or a jog switch, which is located on the rear or side surface of the electronic device 1. The touch input means may include a touch screen layer of the display panel 10.

The second input module 1320 may be connected, in a wired or wireless manner, to various types of external electronic device 2000 connected to the electronic device 1. According to one or more embodiments, the second input module 1320 may include a high definition multimedia interface (HDMI), a universal serial bus (USB) interface, a secure digital (SD) card interface, and/or an audio interface. The second input module 1320 may include a connector which is physically connectable to the external electronic device 2000, for example, an HDMI connector, a USB connector, an SD card connector, or an audio connector (e.g., a headphone connector). In response to the connection of the external electronic device 2000 to the second input module 1320, the electronic device 1 may perform appropriate control related to the connected external electronic device 2000.

The display module 1400 may provide visual information to the user. The display module 1400 may include the display panel 10, a scan driver 1420, and the data driver 1430.

The display panel 10 may display (output) information processed by the electronic device 1. The display panel 10 may display execution screen information of an application driven by the electronic device 1, or user interface (UI) or graphic user interface (GUI) information based on the execution screen information.

The scan driver 1420 may be mounted on the display panel 10 as a driving chip. Alternatively, the scan driver 1420 may be formed directly on the display panel 10. For example, the scan driver 1420 may include an amorphous silicon TFT gate driver circuit (ASG), a low temperature polycrystalline silicon (LTPS) TFT gate driver circuit, and/or an oxide semiconductor TFT gate driver circuit (OSG), which is embedded in the display panel 10. The scan driver 1420 may receive a control signal from the controller 1121 and output scan signals to the display panel 10 in response to the control signal.

The display panel 10 may further include an emission control driver. The emission control driver may output an emission control signal to the display panel 10 in response to the control signal received from the controller 1121. The emission control driver may be formed separately from the scan driver 1420 or may be integrated into the scan driver 1420.

The data driver 1430 may receive a control signal from the controller 1121, convert image data into analog voltages (e.g., data voltages) in response to the control signal, and then output the data voltages to the display panel 10.

The data driver 1430 may be integrated with some components of the auxiliary processor 1120. For example, the data driver 1430 may be provided as a timing controller embedded driver integrated circuit (IC) including the controller 1121.

The power module 1500 may supply power to the components of the electronic device 1. The power module 1500 may include a battery which is charged with a power supply voltage. In addition, the power module 1500 may include a connection port. The connection port may be included in the second input module 1320 to which an external charger that supplies power for charging the battery is connected. Alternatively, the power module 1500 may include a wireless power transmission/reception member so as to enable wireless charging of the battery. The wireless power transmission/reception member may include a plurality of coil-type antenna radiators. The power module 1500 may include a power management integrated circuit (PMIC). The PMIC may supply optimized power to each component of the electronic device 1.

The electronic device 1 may further include the internal module 1600 and the external module 1700. The internal module 1600 may include the sensor module 1610, the antenna module 1620, and the audio output module 1630. The external module 1700 may include a camera module 1710, a light module 1720, and/or the communication module 1730.

The sensor module 1610 may include a touch sensor driver and touch electrodes of the touch screen layer of the display panel 10. The sensor module 1610 may sense input by a user's body or input by a pen and may generate an electrical signal or a data value corresponding to the input. The sensor module 1610 may include at least one of a fingerprint sensor 1611, an input sensor 1612, or a digitizer 1613.

The fingerprint sensor 1611 may generate a data value corresponding to a user's fingerprint. The fingerprint sensor 1611 may include at least one of an optical fingerprint sensor or a capacitive fingerprint sensor.

The input sensor 1612 may generate a data value corresponding to coordinate information of the input by the user's body or the input by the pen. The input sensor 1612 may generate a data value based on an amount of change in electrostatic capacitance by the input. The input sensor 1612 may sense input by the passive pen or may transmit and receive data to and from the active pen.

The input sensor 1612 may also measure biometric signals, such as blood pressure, moisture, and/or body fat. For example, in case that the user touches a part of his/her body to a sensor layer or a sensing panel and does not move for a certain time, the input sensor 1612 may detect biometric signals based on a change in electric field caused by the part of his/her body and output information desired by the user to the display module 1400.

The digitizer 1613 may generate a data value corresponding to coordinate information input by the pen. The digitizer 1613 may generate a data value based on an amount of change in electromagnetism by the input. The digitizer 1613 may sense input by the passive pen, or may transmit and receive data to and from the active pen.

In one or more embodiments, at least one of the fingerprint sensor 1611, the input sensor 1612, or the digitizer 1613 may be embedded into the display panel 10. For example, at least one of the fingerprint sensor 1611, the input sensor 1612, or the digitizer 1613 may be formed through a process that is continuous with the process of forming the pixel circuits and the light-emitting diodes of the display panel 10. Due to this, the display panel 10 may function as one of the input modules 1300 configured to provide an input interface between the electronic device 1 and the user and may also function as the display module 1400 configured to provide an output interface between the electronic device 1 and the user.

In one or more embodiments, at least two of the fingerprint sensor 1611, the input sensor 1612, or the digitizer 1613 may be integrated into a single sensing panel through the same process. The sensing panel may be disposed between the display panel 10 and a window on the upper side of the display panel 10, but the present disclosure is not limited thereto.

The antenna module 1620 may include one or more antennas that transmit signals or power to the outside or receive signals or power from the outside. According to one or more embodiments, the communication module 1730 may transmit and/or receive signals to and from an external electronic device through an antenna suitable for a communication scheme. An antenna pattern of the antenna module 1620 may be integrated into one component of the display module 1400 (e.g., the display panel 10) or the input sensor 1612.

The audio output module 1630 is a device configured to output an audio signal to the outside of the electronic device 1 and may output audio data received from the communication module 1730 or stored in the memory 1200 in a call signal reception mode, a call mode, a recording mode, a voice recognition mode, a broadcast reception mode, etc. The audio output module 1630 may output an audio signal related to the function performed in the electronic device 1 (e.g., a call signal reception sound, a message reception sound, etc.). The audio output module 1630 may include a receiver and a speaker. At least one of the receiver or the speaker may be a sound generation device that is attached to the lower portion of the display panel 10 and vibrates the display panel 10 to output sound. The sound generation device may be a piezoelectric element and/or a piezoelectric actuator that contracts and expands in response to an electrical signal, or may be an exciter that generates a magnetic force by using a voice coil and vibrates the display panel 10.

The camera module 1710 may capture still images and/or moving images. According to one or more embodiments, the camera module 1710 may include one or more lenses, image sensors, and/or image signal processors. The camera module 1710 may further include an IR camera capable of measuring the presence or absence of the user, the user's location, the user's line of sight, and/or the like.

The light module 1720 may output a signal to notify the occurrence of an event by using light from a light source or provide light so as to obtain an image. Examples of the occurrence of the event may include message reception, call signal reception, missed call, alarm, schedule reminder, email reception, and notification of battery charge capacity information. The light module 1720 may include a light-emitting diode or a xenon lamp. The light module 1720 may emit light of one or more colors to the front or back of the electronic device 1. The light module 1720 may operate in conjunction with the camera module 1710 or may operate independently.

The communication module 1730 may support establishment of a wired or wireless communication channel between the electronic device 1 and the external electronic device 2000 and may support performance of communication through the established communication channel. The communication module 1730 may include one or all of a wireless communication module (e.g., a cellular communication module, a short-range wireless communication module, and/or a global navigation satellite system (GNSS) communication module) and a wired communication module (e.g., a local area network (LAN) communication module or a power line communication module). The communication module 1730 may transmit and receive wireless signals on the Internet by using at least one of wireless LAN (WLAN), wireless-fidelity/Wi-Fi®(Wi-Fi®being a registered trademark of the non-profit Wi-Fi Alliance), Wi-Fi Direct™ (Wi-Fi Direct™ being a registered trademark of the non-profit Wi-Fi Alliance), or digital living network alliance (DLNA). In addition, the communication module 1730 may support short-range communication by using at least one of Bluetooth^{®}(Bluetooth®being a registered trademark of Bluetooth Sig, Inc., Kirkland, WA), radio frequency identification (RFID), infrared data association (IrDA), ultra wideband (UWB), Zigbee®(ZigBee®being a registered trademark of Connectivity Standards Alliance, CA), NFC, Wi-Fi®, Wi-Fi Direct™, or a wireless USB. Various types of the communication module 1730 described above may be implemented as a single chip or separate chips.

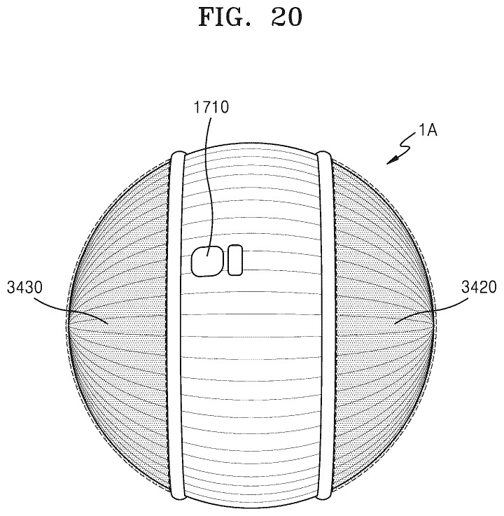

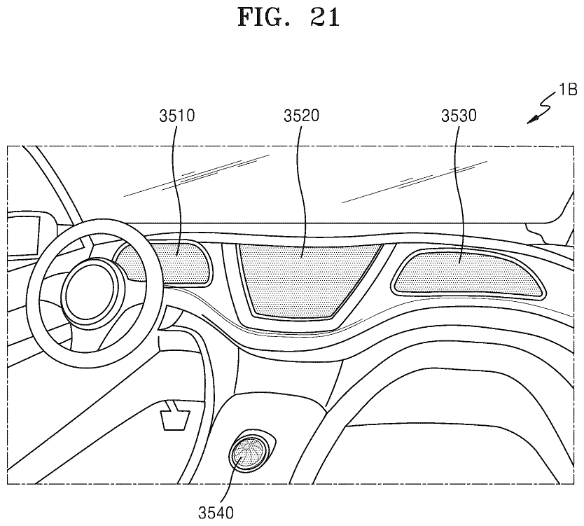

In the embodiment described above with reference to FIGS. 18 and 19, the display panel 10 is described as being included in the electronic device 1 that is freely deformed three-dimensionally to provide a three-dimensionally deformable image surface, but the present disclosure is not limited thereto. As illustrated in FIGS. 20 and 21, the electronic device includes an image providing area having a fixed shape, but in a process of manufacturing the electronic device, the display panel may be disposed in the image providing area of the electronic device described above and the display panel may be fixed to the electronic device in a three-dimensionally deformed state.

FIGS. 20 and 21 are perspective views illustrating an electronic device according to one or more embodiments.

FIG. 20 illustrates a robot as an electronic device 1A according to one or more embodiments. The robot may recognize movement or objects by using a camera module 1710 and may display certain images to a user on displays 3420 and 3430. In one or more embodiments, the display panels may be stretched in various directions, as described above. Accordingly, while being stretched three-dimensionally along a body frame having a semispherical shape, the display panels may be assembled into a frame of the electronic device 1A to form the displays 3420 and 3430.

FIG. 21 illustrates a vehicle display device as an electronic device 1B according to one or more embodiments. The vehicle display device may include a cluster 3510, a center information display (CID) 3520, and/or a co-driver display (or a passenger display) 3530. Because the display panel according to one or more embodiments may be stretched in various directions, the display panel may be used in the cluster 3510, the CID 3520, and/or the co-driver display (or the passenger display) 3530, regardless of the shape of the internal frame of the vehicle.

Although FIG. 21 illustrates that the cluster 3510, the CID 3520, and/or the co-driver display (or the passenger display) 3530 are separated from each other, the present disclosure is not limited thereto. In one or more embodiments, two or more selected from the cluster 3510, the CID 3520, and the co-driver display (or the passenger display) 3530 may be integrally connected to each other.

In one or more embodiments, the vehicle display device may include a button 3540 configured to display a certain image. The button 3540 having a hemispherical shape may sense touch input from a user (e.g., a driver) in a +z direction or a −z direction.

FIGS. 20 and 21 illustrate that the electronic devices 1A and 1B are used for a robot or a vehicle, but the present disclosure is not limited thereto. The electronic devices according to the present disclosure may include electronic devices for various purposes, such as commercial electronic devices, office electronic devices, educational electronic devices, wearable electronic devices, medical electronic devices, and/or the like. In other words, the display panels according to one or more embodiments may be provided in various electronic devices as long as the display panels include an area capable of providing an image.

According to one or more embodiments, a display panel with improved elasticity and an electronic device including the same may be provided. For example, separation of components of the display panel may be prevented when the display panel is stretched. The effects, aspects, and features described above are illustrative, and the effects, aspects, and features of the present disclosure are not limited to those described above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display panel comprising:
a base layer;
a first pixel circuit layer on the base layer, the first pixel circuit layer comprising a transistor and insulating layers;
a second pixel circuit layer on the base layer and spaced from the first pixel circuit layer, the second pixel circuit layer comprising a transistor and insulating layers;
a first light-emitting diode on the first pixel circuit layer and electrically connected to the transistor of the first pixel circuit layer;
a second light-emitting diode on the second pixel circuit layer and electrically connected to the transistor of the second pixel circuit layer; and
a protective layer on the first light-emitting diode and the second light-emitting diode,
wherein the insulating layers of each of the first pixel circuit layer and the second pixel circuit layer comprise:
an inorganic insulating stack comprising inorganic insulating layers; and
a first organic insulating layer on the inorganic insulating stack,
wherein the first organic insulating layer of the first pixel circuit layer and the first organic insulating layer of the second pixel circuit layer are spaced from each other, and
wherein the first organic insulating layer of the first pixel circuit layer includes first grooves arranged along an edge thereof and a portion of the protective layer is in each of the first grooves.

2. The display panel of claim 1, wherein each of the first grooves includes:
a first portion having a first width; and
a second portion spatially connected to the first portion and having a second width greater than the first width.

3. The display panel of claim 2, wherein the first portion of each of the first grooves extends toward the edge of the first organic insulating layer and, in a plan view, the first portion of each of the first grooves is between the edge of the first organic insulating layer and the second portion of each of the first grooves.

4. The display panel of claim 1, further comprising:
a first line electrically connected to the transistor of the first pixel circuit layer;
a second line electrically connected to the transistor of the second pixel circuit layer; and
a connection line electrically connecting the first line to the second line.

5. The display panel of claim 4, wherein the first line is between two adjacent first grooves from among the first grooves.

6. The display panel of claim 5, wherein the first organic insulating layer of the first pixel circuit layer overlaps a connection point of the first line and the connection line.

7. The display panel of claim 1, wherein the insulating layers of the first pixel circuit layer further comprise a second organic insulating layer on the first organic insulating layer,
wherein the second organic insulating layer includes a second groove at an edge of the second organic insulating layer, and
wherein a portion of the protective layer is in the second groove.

8. The display panel of claim 7, wherein the second groove includes:
a first portion; and
a second portion spatially connected to the first portion and having a width greater than a width of the first portion.

9. The display panel of claim 7, wherein the insulating layers of the first pixel circuit layer further comprise a third organic insulating layer covering a side surface of the inorganic insulating stack of the first pixel circuit layer and,
wherein, in a plan view, the third organic insulating layer has a frame shape.

10. The display panel of claim 1, wherein the protective layer and the base layer comprise a same material.

11. A display panel comprising:
a base layer comprising a first surface and a second surface opposite to the first surface;
a first pixel circuit layer on the first surface of the base layer, the first pixel circuit layer comprising a transistor and insulating layers;
a second pixel circuit layer on the first surface of the base layer and spaced from the first pixel circuit layer, the second pixel circuit layer comprising a transistor and insulating layers;
a first light-emitting diode on the first pixel circuit layer and electrically connected to the transistor of the first pixel circuit layer;
a second light-emitting diode on the second pixel circuit layer and electrically connected to the transistor of the second pixel circuit layer;
a protective layer on the first light-emitting diode and the second light-emitting diode;
a first line electrically connected to the transistor of the first pixel circuit layer;
a second line electrically connected to the transistor of the second pixel circuit layer; and
a connection line electrically connecting the first line to the second line,
wherein the insulating layers of each of the first pixel circuit layer and the second pixel circuit layer comprise a first organic insulating layer, the first organic insulating layer of the first pixel circuit layer and the first organic insulating layer of the second pixel circuit layer being spaced from each other, and
wherein the first organic insulating layer of the first pixel circuit layer includes a first groove at an edge of the first organic insulating layer, the first groove includes a first portion having a first width and a second portion having a second width different from the first width, and a portion of the protective layer is in the first groove.

12. The display panel of claim 11, wherein the second width is greater than the first width.

13. The display panel of claim 12, wherein the first portion of the first groove extends toward the edge of the first organic insulating layer.

14. The display panel of claim 11, wherein the first organic insulating layer of the first pixel circuit layer overlaps a connection point of the first line and the connection line.

15. The display panel of claim 14, wherein the insulating layers of the first pixel circuit layer further comprise a second organic insulating layer on the first organic insulating layer,
wherein the second organic insulating layer includes a second groove at an edge of the second organic insulating layer, and
wherein a portion of the protective layer is in the second groove.

16. The display panel of claim 15, wherein the second groove overlaps the first organic insulating layer.

17. The display panel of claim 15, wherein the second groove includes:
a first portion; and
a second portion spatially connected to the first portion and having a width greater than a width of the first portion.

18. The display panel of claim 11, wherein the insulating layers of the first pixel circuit layer further comprise an inorganic insulating stack between the base layer and the first organic insulating layer, and
wherein the first groove does not overlap the inorganic insulating stack.

19. The display panel of claim 11, wherein the protective layer is in direct contact with the connection line and the base layer, and
wherein the protective layer and the base layer comprise a same material.

20. An electronic device comprising a display panel, the display panel comprising:
a base layer;
a first pixel circuit layer on the base layer, the first pixel circuit layer comprising a transistor and insulating layers;
a second pixel circuit layer on the base layer and spaced from the first pixel circuit layer, the second pixel circuit layer comprising a transistor and insulating layers;
a first light-emitting diode on the first pixel circuit layer and electrically connected to the transistor of the first pixel circuit layer;
a second light-emitting diode on the second pixel circuit layer and electrically connected to the transistor of the second pixel circuit layer; and
a protective layer on the first light-emitting diode and the second light-emitting diode,
wherein the insulating layers of each of the first pixel circuit layer and the second pixel circuit layer comprise:
an inorganic insulating stack comprising inorganic insulating layers; and
a first organic insulating layer on the inorganic insulating stack,
wherein the first organic insulating layer of the first pixel circuit layer and the first organic insulating layer of the second pixel circuit layer are spaced from each other, and
wherein the first organic insulating layer of the first pixel circuit layer includes first grooves arranged along an edge thereof and a portion of the protective layer is in each of the first grooves.
